(19) United States
(12) Patent Application Publication
(10) Pub. No.: US 2025/0022869 A1
(43) Pub. Date: Jan. 16, 2025

(54) METHODS OF MANUFACTURING SEMICONDUCTOR DIE STACK STRUCTURES

(71) Applicant: SK hynix Inc., Icheon-si Gyeonggi-do (KR)

(72) Inventors: Sung Kyu KIM, Icheon-si Gyeonggi-do (KR); Jong Yeon KIM, Icheon-si Gyeonggi-do (KR); Ki Ill MOON, Icheon-si Gyeonggi-do (KR); Sang Yong LEE, Icheon-si Gyeonggi-do (KR); Gyu Jei LEE, Icheon-si Gyeonggi-do (KR)

(73) Assignee: SK hynix Inc., Icheon-si Gyeonggi-do (KR)

(21) Appl. No.: 18/532,685

(22) Filed: Dec. 7, 2023

(30) Foreign Application Priority Data
Jul. 12, 2023 (KR) 10-2023-0090631

(51) Int. Cl. H01L 25/00; H01L 23/00; H01L 25/065; H01L 25/18; H10B 80/00

(52) U.S. Cl. CPC H01L 25/50; H01L 24/08; H01L 24/80; H01L 25/0657; H01L 25/18; H10B 80/00; H01L 2224/08146; H01L 2224/80006; H01L 2224/80895; H01L 2224/80896; H01L 2225/06513; H01L 2225/06541; H01L 2225/06586; H01L 2924/1431; H01L 2924/1434

(57) ABSTRACT

A method of manufacturing a semiconductor die stack structure includes: preparing a base die including a base die substrate and a base die inter-layer dielectric layer; forming a base die front-side bonding pad structure; preparing a bottom die having a bottom die substrate and bottom die through-electrode; forming a bottom die front-side bonding pad structure in the bottom die substrate; forming a base-bottom die stack structure where the bottom die front-side bonding pad structure is directly in contact with the base die front-side; forming a base die through-electrode vertically passing through the base die substrate and electrically connected to the base die front-side bonding pad structure; forming a base die back-side bump structure electrically connected to the base die through-electrode; stacking middle dies and a top die in the base-bottom die stack structure; and forming a bottom die back-side bump structure electrically connected to the bottom die through-electrode.

### CROSS-REFERENCE TO RELATED APPLICATION

The present application claims priority under 35 U.S.C 119 (a) to Korean Patent Application No. 10-2023-0090631, filed on Jul. 12, 2023, in the Korean Intellectual Property Office, which is incorporated herein by reference in its entirety.

### BACKGROUND

### 1. Technical Field

Embodiments of the present disclosure generally relate to semiconductors, and more particularly, to semiconductor die stack structures and methods of fabricating the semiconductor die stack structures.

### 2. Related Art

Disclosed is a semiconductor die stack structure including a plurality of semiconductor dies.

### SUMMARY

In accordance with an embodiment of the present disclosure, a method of manufacturing a semiconductor die stack structure includes: preparing a base die including a base die substrate and a base die inter-layer dielectric layer; forming a base die front-side bonding pad structure over the base die inter-layer dielectric layer; preparing a bottom die having a bottom die substrate and bottom die through-electrode; forming a bottom die front-side bonding pad structure over a front-side of the bottom die substrate; forming a base-bottom die stack structure in which the bottom die front-side bonding pad structure and the base die front-side bonding pad structure are directly in contact with each other by bonding the bottom die and the base die; forming a base die through-electrode vertically passing through the base die substrate and electrically connected to the base die front-side bonding pad structure; forming a base die back-side bump structure electrically connected to the base die through-electrode over a back-side of the base die substrate; stacking a plurality of middle dies over the base die of the base-bottom die stack structure; stacking a top die over the plurality of middle dies; and forming a bottom die back-side bump structure electrically connected to the bottom die through-electrode.

In accordance with another embodiment of the present disclosure, a method of manufacturing a semiconductor die stack structure includes: preparing a base die having a base die substrate and a base die inter-layer dielectric layer; forming a base die front-side bonding pad structure over the base die inter-layer dielectric layer; preparing a bottom die having a bottom die substrate and bottom die through-electrode; forming a bottom die front-side bonding pad structure over a front-side of the bottom die substrate; forming a base-bottom die stack structure in which the bottom die front-side bonding pad structure and the base die front-side bonding pad structure are directly in contact with each other by bonding the bottom die and the base die; forming a base die through-electrode vertically passing through the base die substrate and electrically connected to the base die front-side bonding pad structure; forming a base die back-side bump structure electrically connected to the base die through-electrode over a back-side of the base die substrate; forming a bottom die back-side bump structure over the base-bottom die stack structure; stacking middle dies over the bottom die of the base-bottom die stack structure; and stacking a top die over the middle dies.

In accordance with another embodiment of the present disclosure, a semiconductor die stack structure includes: a bottom die; a base die stacked over the bottom die; and middle dies and a top die that are stacked over the base die, wherein the bottom die includes: a bottom die substrate; a bottom die front-side bonding pad structure disposed over a front-side of the bottom die substrate; a bottom die back-side bump structure disposed over a back-side of the bottom die substrate; and a bottom die through-electrode passing through the bottom die substrate and electrically connecting the bottom die front-side bonding pad structure and the bottom die back-side bump structure, and the base die includes: a base die substrate; a base die front-side bonding pad structure disposed over a front-side of the base die substrate; a base die back-side bump structure disposed over a back-side of the base die substrate; and a base die through-electrode passing through the base die substrate and electrically connecting the base die front-side bonding pad structure and the base die back-side bump structure, and the bottom die front-side bonding pad structure and the base die front-side bonding pad structure are bonded by being directly in contact with each other.

In accordance with another embodiment of the present disclosure, a semiconductor die stack structure includes: a base die; a bottom die stacked over the base die; and middle dies and a top die that are stacked over the base die, wherein the base die includes: a base die substrate; a base die front-side bonding pad structure disposed over a front-side of the base die substrate; a base die back-side bump structure disposed over a back-side of the base die substrate; and a base die through-electrode passing through the base die substrate and electrically connecting the base die front-side bonding pad structure and the base die back-side bump structure, and the bottom die includes: a bottom die substrate; a bottom die front-side bonding pad structure disposed over a front-side of the bottom die substrate; a bottom die back-side bump structure disposed over a back-side of the bottom die substrate; and a bottom die through-electrode passing through the bottom die substrate and electrically connecting the bottom die front-side bonding pad structure and the bottom die back-side bump structure, and the bottom die front-side bonding pad structure and the base die front-side bonding pad structure are bonded by being directly in contact with each other.

### BRIEF DESCRIPTION OF THE DRAWINGS

FIGS. 1A, 1B, 2A, 2B, 2C, 2D, 3A, 3B, 3C, 3D, 3E, 4A, 4B, 5A, 5B, 5C, 5D, 5E, 5F, 6A, 6B, 6C, 6D, 6E, 6F, 6G, 7A, 7B, 8A, 8B, 8C, 8D, 8E, 8F, 8G, 8H, 9A, 9B, 10A, 10B, 10C, 10D, 10E, 10F, 11A, and 11B illustrate a method of manufacturing semiconductor die stack structures in accordance with various embodiments of the present disclosure.

### DETAILED DESCRIPTION

Embodiments of the present disclosure will be described below in more detail with reference to the accompanying drawings. The present disclosure may, however, be embodied in different forms and should not be construed as limited to the embodiments set forth herein. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly. Embodiments of the present disclosure are directed to a semiconductor die stack structure including a plurality of semiconductor dies that are stacked therein, and a method of manufacturing the semiconductor die stack structure. Embodiments of the present disclosure are directed to a base-bottom die stack structure in which a base die and a bottom die are bonded, and a method of manufacturing the base-bottom die stack structure. Embodiments of the present disclosure are directed to a method of stacking middle dies and a top die over a base-bottom die stack structure. Embodiments of the present disclosure are directed to a semiconductor stack structure including middle dies and a top die that are stacked over a base-bottom die stack structure.

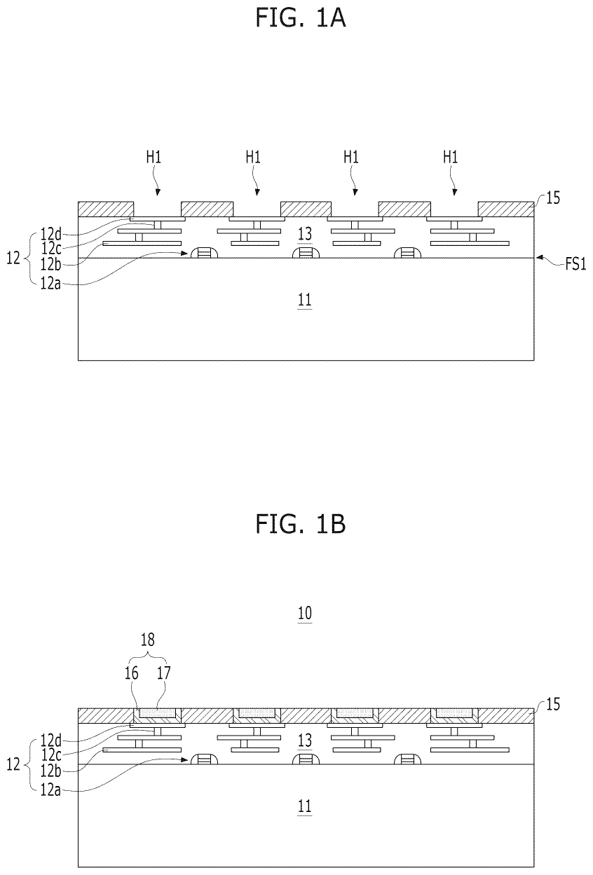

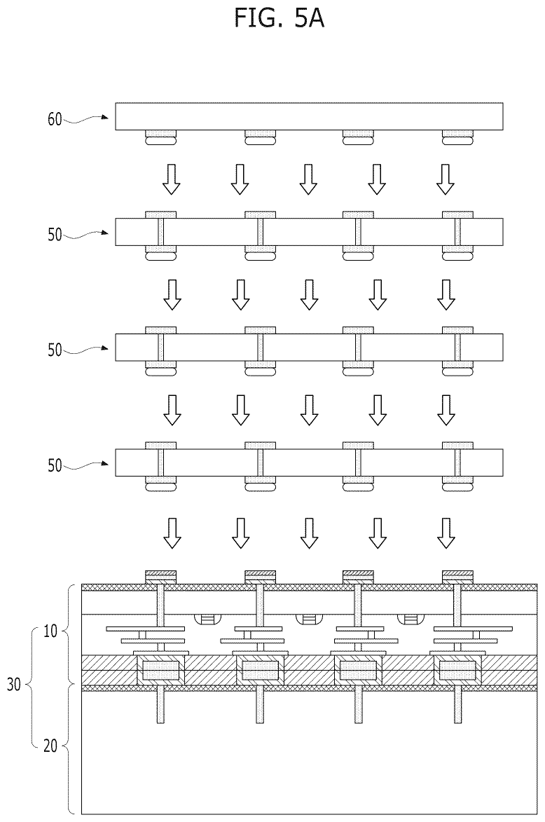

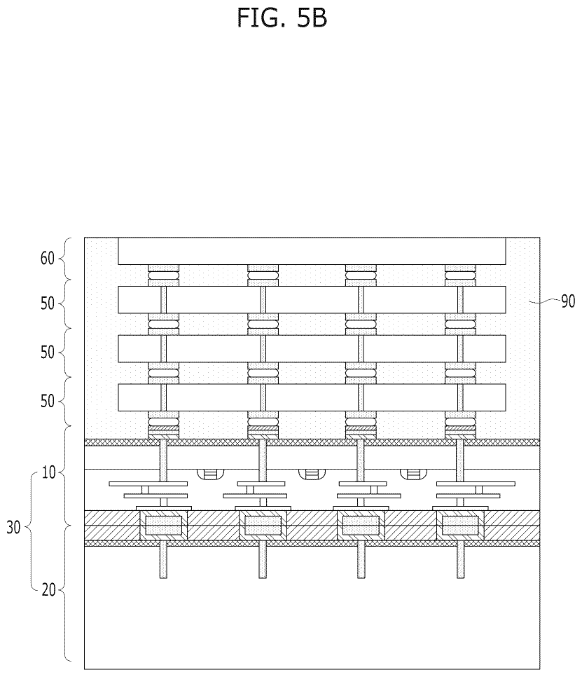

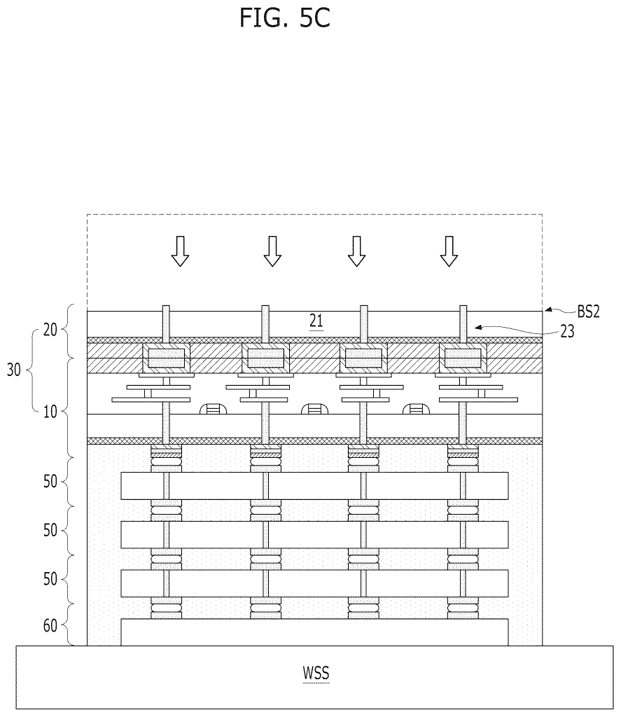

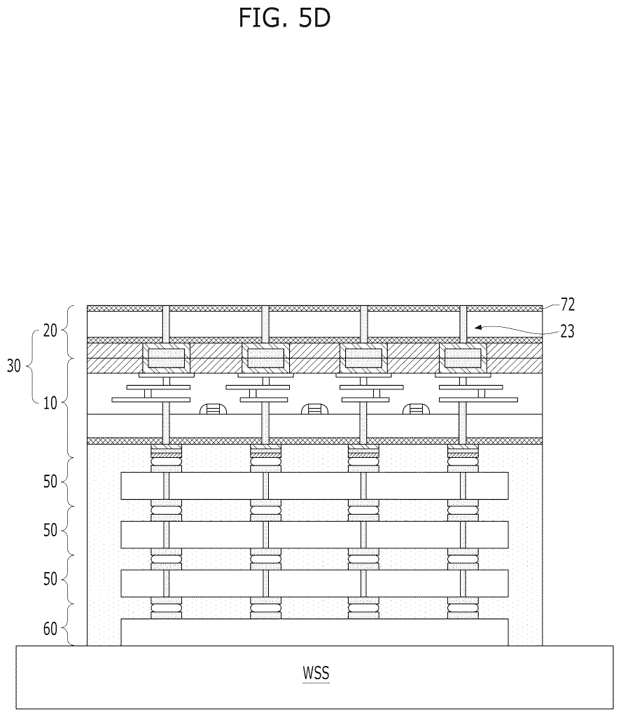

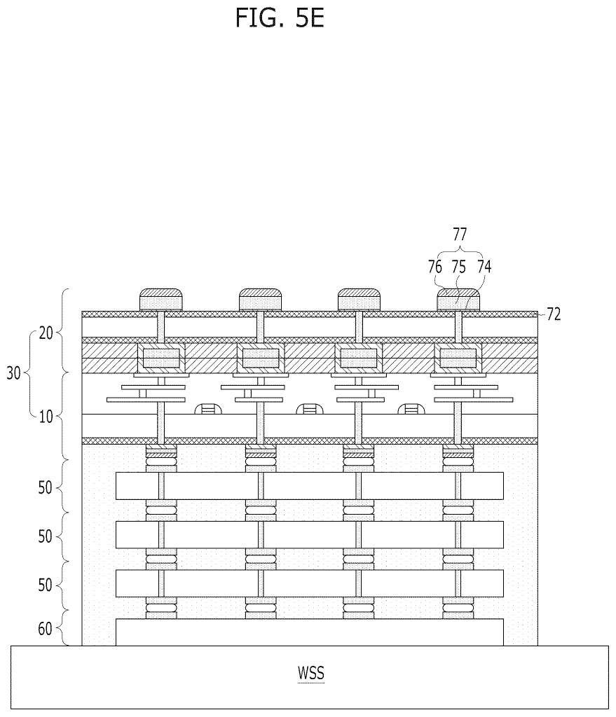

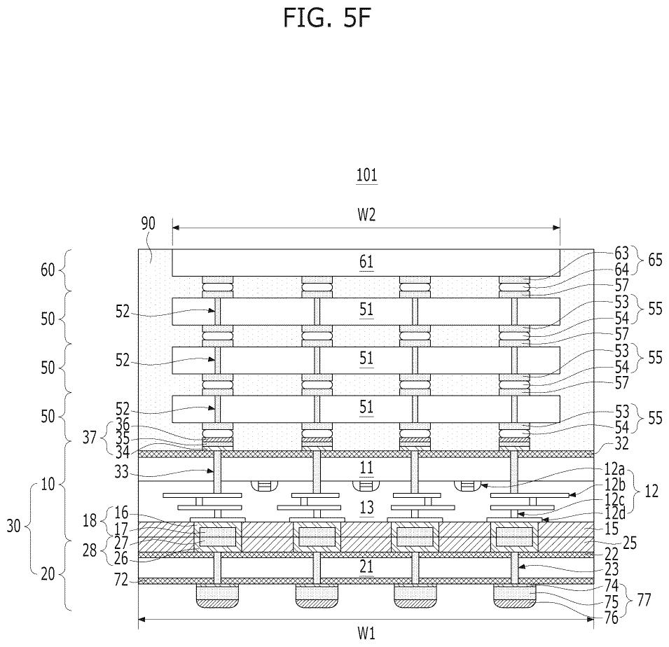

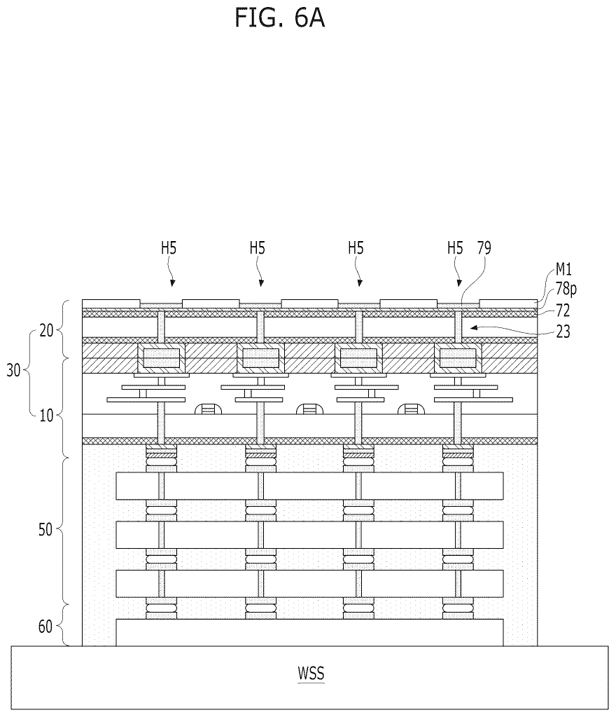

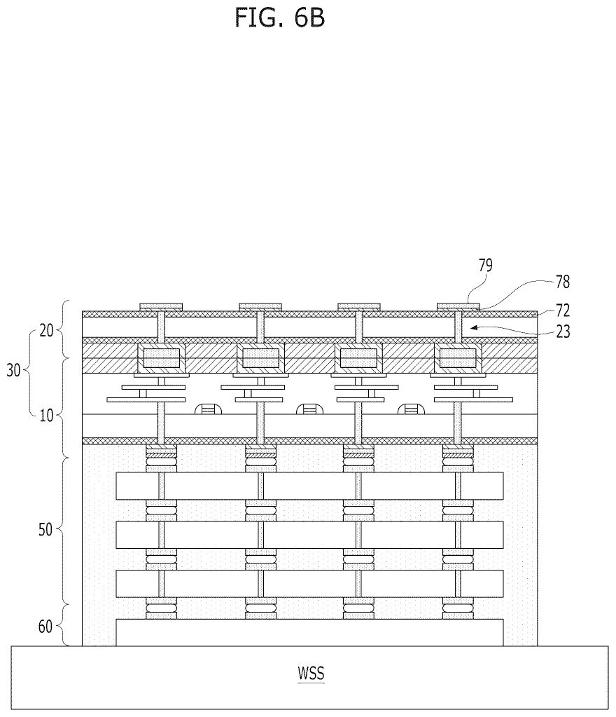

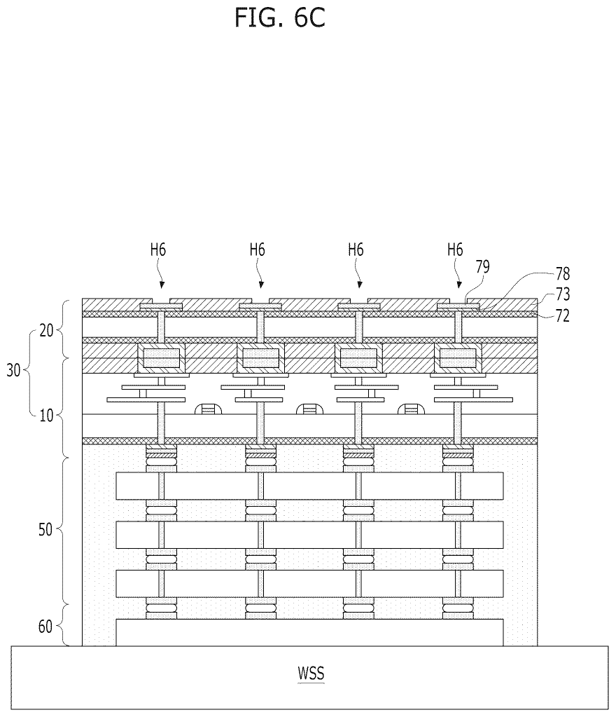

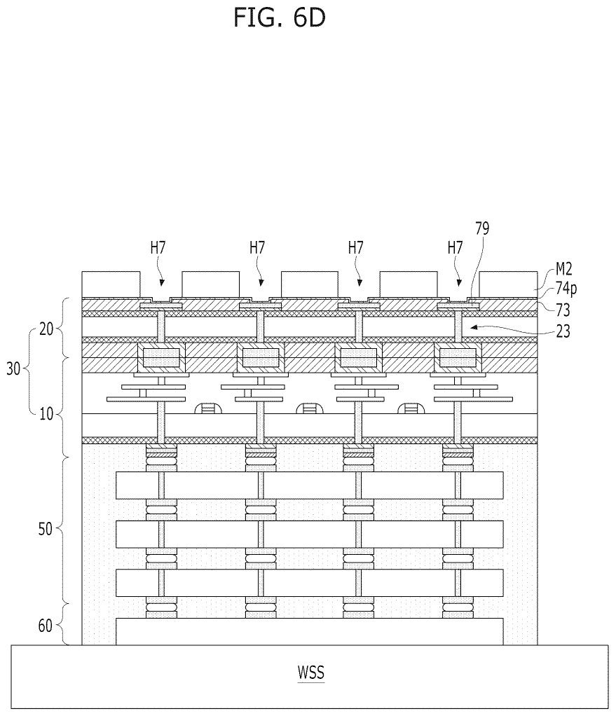

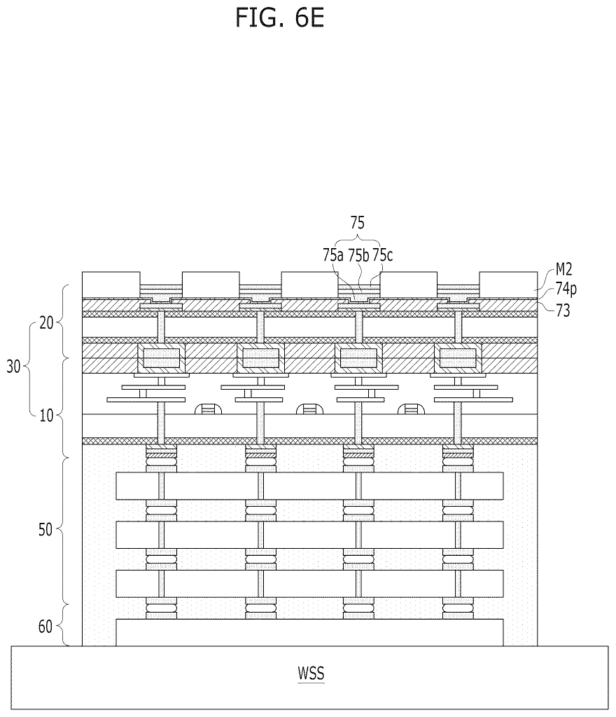

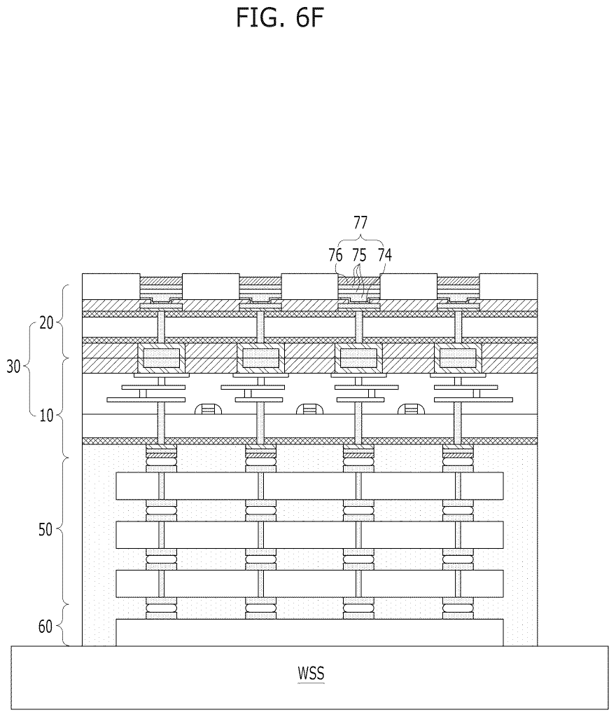

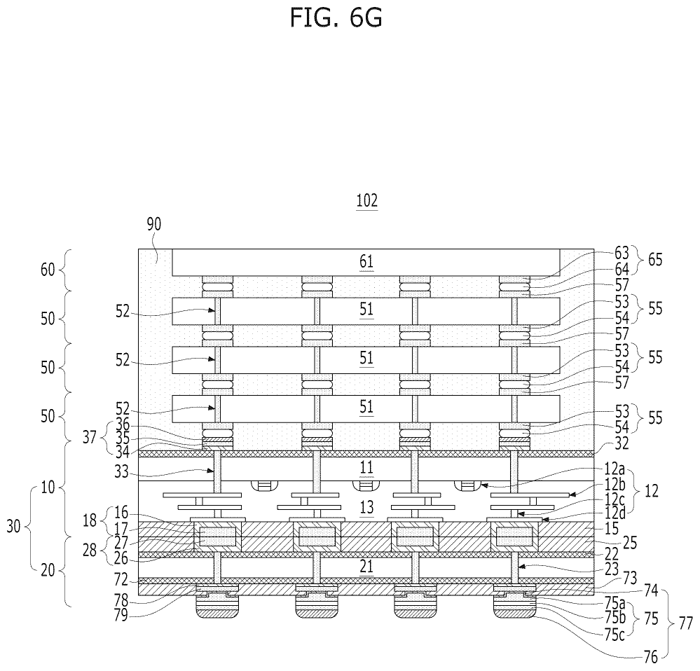

FIGS. 1A to 6G illustrate a method of manufacturing semiconductor die stack structures 101 and 102 (of FIGS. 5F and 6G, respectively) in accordance with embodiments of the present disclosure. Referring to FIGS. 1 to 6G, a method of manufacturing semiconductor die stack structures 101 and 102 may include preparing a base die 10, preparing a bottom die 20, preparing a base-bottom die stack structure 30 by bonding the base die 10 and the bottom die 20, preparing middle dies 50 and a top die 60, stacking the middle dies 50 and the top die 60 over the base-bottom die stack structure 30, and performing a dicing process.

FIGS. 1A and 1B illustrate manufacturing and preparing the base die 10 in the methods of manufacturing semiconductor die stack structures (101 in FIG. 5F and 102 in FIG. 6G) in accordance with embodiments of the present disclosure.

Referring to FIG. 1A, the method may include forming base die circuit elements 12 and a base die inter-layer dielectric layer 13 over a front-side (active side) FS1 of a base die substrate 11, and forming a base die front-side bonding dielectric layer 15 over the base die circuit elements 12 and the base die inter-layer dielectric layer 13.

The base die substrate 11 may include a silicon wafer. The base die circuit elements 12 may include base die transistors 12a, base die metal interconnections 12b, base die metal vias 12c, and base die metal pads 12d. For example, the base die circuit elements 12 may include memory peripheral logic circuits. The base die metal interconnections 12b may extend in a horizontal direction and transfer electrical signals. The base die metal vias 12c may extend in a vertical direction to electrically connect the base die transistors 12a, the base die metal interconnections 12b, and the base die metal pads 12d. The base die inter-layer dielectric layer 13 may be formed over the base die substrate 11 to cover the base die circuit elements 12. The base die inter-layer dielectric layer 13 may include a silicon oxide-based or silicon nitride-based dielectric material.

The base die front-side bonding dielectric layer 15 may include an inorganic dielectric layer. For example, the base die front-side bonding dielectric layer 15 may include at least one of silicon oxide, silicon nitride, silicon oxynitride, and other inorganic dielectric materials containing silicon, oxygen, and/or nitrogen. The base die front-side bonding dielectric layer 15 may have holes H1 exposing surfaces of the base die metal pads 12d.

Referring to FIG. 1B, the method may further include forming base die front-side bonding pad structures 18. The base die front-side bonding pad structures 18 may include base die front-side bonding pad seed layers 16 that are conformally formed on side surfaces of the exposed base die front-side bonding dielectric layer 15 and the surfaces of the exposed base die metal pads 12d in the holes H1, and base die front-side bonding pad metals 17 that are formed over the base die front-side bonding pad seed layers 16 to fill the holes H1. The base die front-side bonding pad seed layers 16 may be conformally formed by performing a deposition process, such as a Physical Vapor Deposition (PVD) process. According to one embodiment of the present disclosure, each of the base die front-side bonding pad seed layers 16 may include a lower base die front-side bonding pad seed layer including titanium (Ti), titanium nitride (TiN), or titanium tungsten (TiW) and an upper base die front-side bonding pad seed layer including copper (Cu). The base die front-side bonding pad metals 17 may be formed by performing a plating process. According to one embodiment of the present disclosure, the base die front-side bonding pad metals 17 may include a metal, such as copper (Cu) and/or nickel (Ni). The base die front-side bonding pad seed layers 16 may respectively surround the lower surfaces and side surfaces of the base die front-side bonding pad metals 17 in a U-shape.

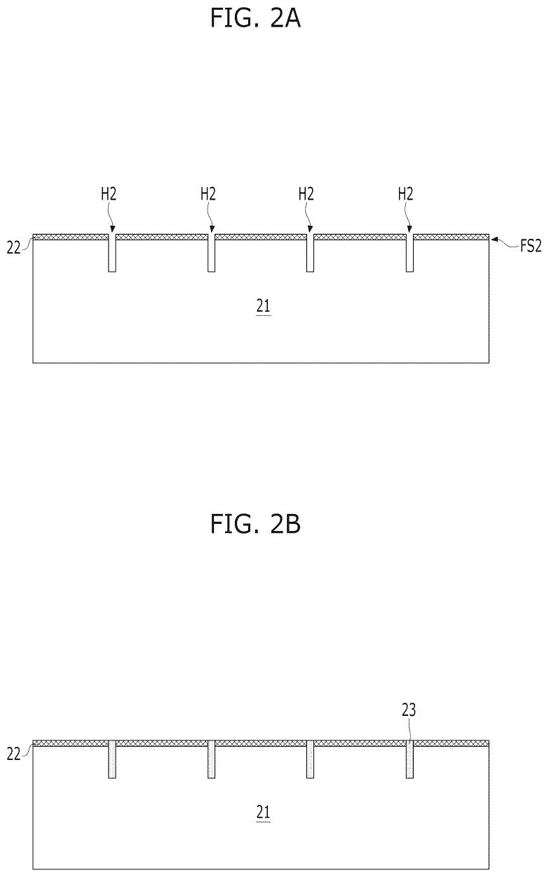

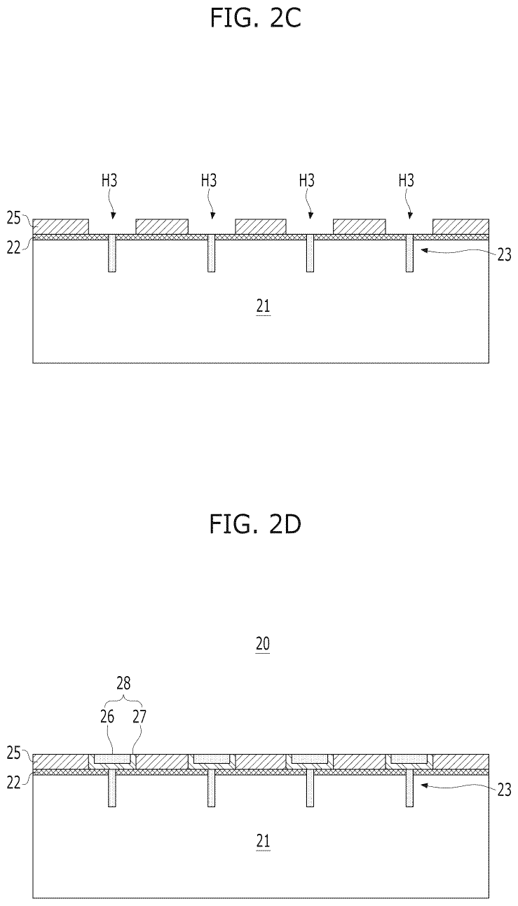

FIGS. 2A to 2D illustrate manufacturing and preparing the bottom die 20 in the methods of manufacturing semiconductor die stack structures (101 in FIG. 5E and 102 in FIG. 6G) in accordance with embodiments of the present disclosure.

Referring to FIG. 2A, the method may include performing a deposition process, such as a Chemical Vapor Deposition (CVD) process to form a bottom die front-side passivation layer 22 over a front-side FS2 of the bottom die substrate 21 of a wafer state, and forming holes H2. The bottom die substrate 21 may include a silicon wafer. The bottom die front-side passivation layer 22 may include an inorganic dielectric layer based on silicon nitride or silicon oxide. The holes H2 may be formed by performing a photolithography process and an etching process. The holes H2 may completely penetrate the bottom die front-side passivation layer 22 and may partially penetrate the bottom die substrate 21. For example, the bottom surfaces of the holes H2 may be disposed in the bottom die substrate 21.

Referring to FIG. 2B, the method may further include forming bottom die through-electrodes 23 in the holes H2. Each of the bottom die through-electrodes 23 may include a bottom die through-electrode plug, a bottom die through-electrode seed layer surrounding the side surfaces of the bottom die through-electrode plug, and a bottom die through-electrode dielectric layer covering side surfaces of the bottom die through-electrode seed layer. The bottom die through-electrode dielectric layer may be conformally formed on the inner walls and bottom surfaces of the holes H2 by performing a Chemical Vapor Deposition (CVD) process or an Atomic Layer Deposition (ALD) process. The bottom die through-electrode dielectric layer may include a silicon oxide-based or silicon nitride-based inorganic dielectric layer. The bottom die through-electrode seed layer may include a metal or a metal compound that is formed by performing a CVD process or a PVD process. The bottom die through-electrode seed layer may be conformally formed over the bottom die through-electrode dielectric layer. According to one embodiment of the present disclosure, the bottom die through-electrode seed layer may include a lower bottom die through-electrode seed layer and an upper bottom die through-electrode seed layer. The lower bottom die through-electrode seed layer may include titanium (Ti), titanium nitride (TiN), or titanium tungsten (TiW). The upper bottom die through-electrode seed layer may include copper (Cu). The bottom die through-electrode plug may be formed to completely fill the holes H2 over the bottom die through-electrode seed layer. The bottom die through-electrode plug may include copper (Cu) which is formed by performing a plating process. The upper surfaces of the bottom die through-electrodes 23 may be exposed. The upper surfaces of the bottom die through-electrodes 23 and the upper surface of the bottom die front-side passivation layer 22 may be co-planar.

Referring to FIG. 2C, the method may further include forming a bottom die front-side bonding dielectric layer 25 having holes H3 over the bottom die front-side passivation layer 22. The bottom die front-side bonding dielectric layer 25 may include a silicon oxide-based or silicon nitride-based inorganic dielectric layer, e.g., silicon oxide, silicon nitride, or silicon carbo-nitride which is formed by performing a deposition process, such as CVD. Surfaces of upper ends of the bottom die through-electrodes 23 may be exposed in the holes H3.

Referring to FIG. 2D, the method may further include forming bottom die front-side bonding pad structures 28. Each of the bottom die front-side bonding pad structures 28 may include a bottom die front-side bonding pad seed layer 26 and a bottom die front-side bonding pad metal 27. The bottom die front-side bonding pad seed layer 26 may be conformally formed on the upper surfaces of the exposed bottom die front-side bonding dielectric layer 25 and the upper surfaces of the exposed bottom die through-electrodes 23 in the holes H3 and the side surfaces of the bottom die front-side bonding dielectric layer 25. Each of the bottom die front-side bonding pad seed layers 26 may include a multi-layer metal layer having a lower bottom die front-side bonding pad seed layer and an upper bottom die front-side bonding pad seed layer. The lower bottom die front-side bonding pad seed layer may include titanium (Ti), titanium nitride (TiN), or titanium tungsten (TiW). The upper bottom die front-side bonding pad seed layer may include copper (Cu). The bottom die front-side bonding pad metals 27 may be formed to fill the holes H3 over the bottom die front-side bonding pad seed layers 26. The bottom die front-side bonding pad metal 27 may include copper (Cu). The bottom die front-side bonding pad seed layers 26 may surround the lower surfaces and side surfaces of the bottom die front-side bonding pad metals 27 in a U-shape, respectively.

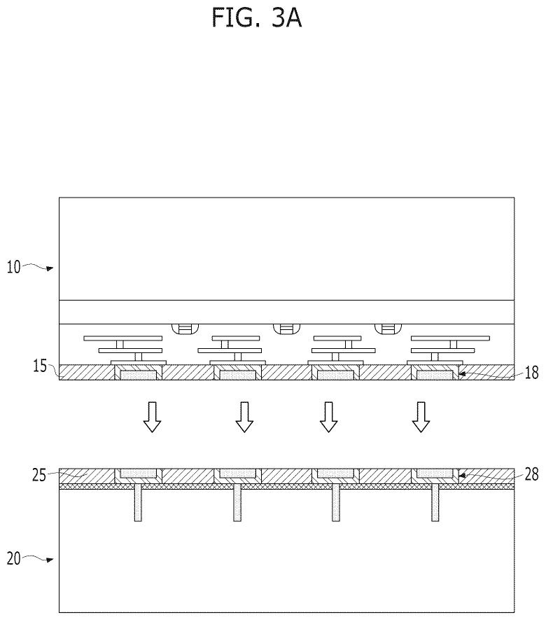

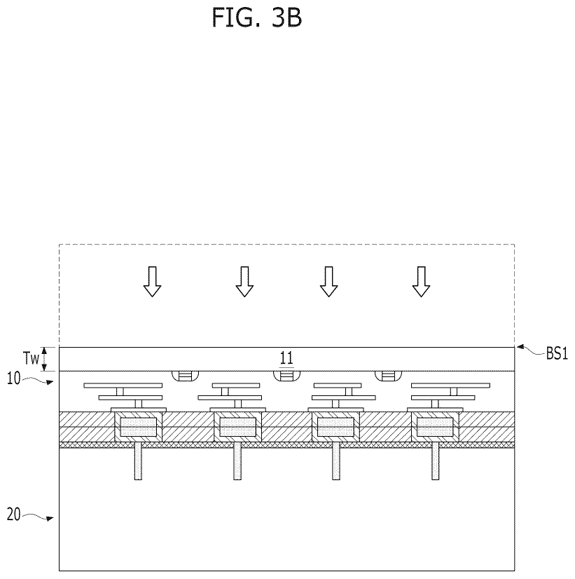

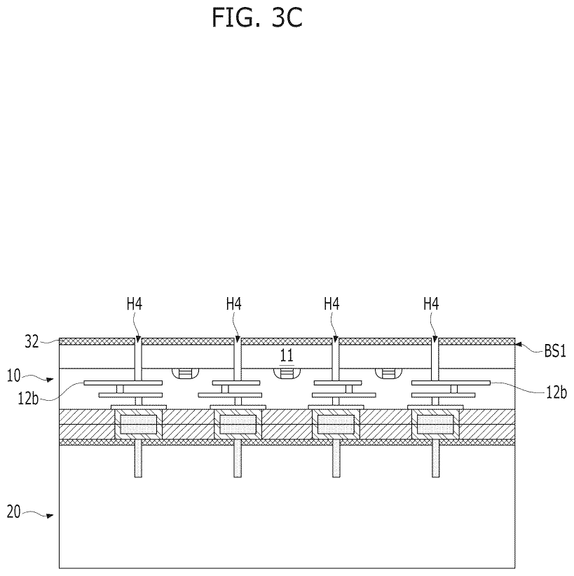

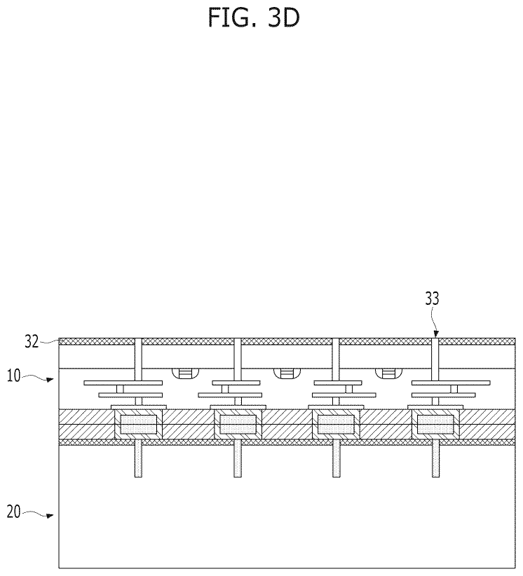

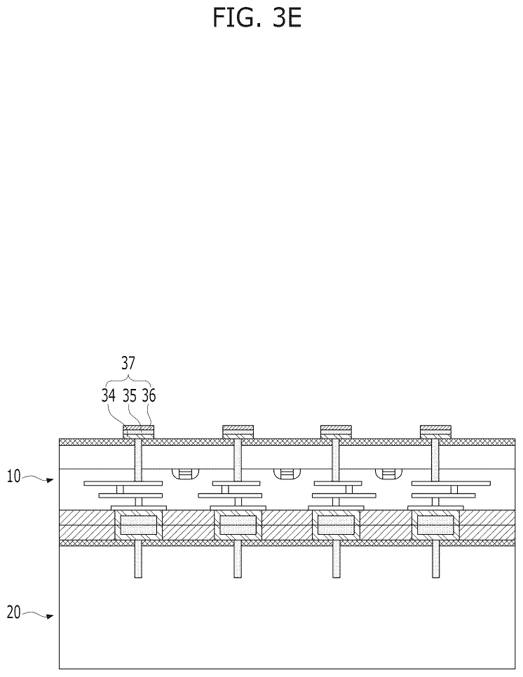

FIGS. 3A to 3E illustrate manufacturing and preparing a plurality of base-bottom die stack structures 30 by bonding the base die 10 and the bottom die 20 and forming base die through-electrodes 33 in a method of manufacturing semiconductor die stack structures (101 in FIG. 5E and 102 in FIG. 61) in accordance with embodiments of the present disclosure.

Referring to FIG. 3A, the method may include bonding a plurality of base dies 10 and a plurality of bottom dies 20 in a wafer-to-wafer manner. For example, the method may include bonding the bottom dies 20 that are faced up, and the base dies 10 that are faced down. In other words, the base dies 10 and the bottom dies 20 may be bonded in a face-to-face manner as indicated by the arrows in FIG. 3A. Each of the bottom dies 20 and each of the base dies 10 may correspond to each other in one-to-one. The base dies 10 and the bottom dies 20 may be bonded using a hybrid bonding method. Each of the base die front-side bonding pad structures 18 and each of the bottom die front-side bonding pad structures 28 may be directly in contact with each other and may be bonded to each other. The base die front-side bonding dielectric layer 15 and the bottom die front-side bonding dielectric layer 25 may be directly in contact with each other and may be bonded to each other through a surface activation process.

Referring to FIG. 3B, the method may further include thinning the back-side (inactive surface) BS1 of the base die substrate 11 by performing a back-grinding process as indicated by the arrows. In the embodiment, the base die substrate 11 may be thinned while being bonded to the bottom die substrate 21 of a wafer state. In an embodiment, because the bonded bottom die substrate 21 has sufficient resistance, the base die substrate 11 may be maintained without being bent or curled during the thinning process. In one embodiment, the thickness Tw of the base die substrate 11 may be as thin as approximately 20 μm or less.

Referring to FIG. 3C, the method may further include forming a base die back-side passivation layer 32 on the back-side BS1 of the base die substrate 11 and forming holes H4. The holes H4 may vertically pass through the thinned base die substrate 11 to selectively expose the surfaces of the base die metal interconnections 12b.

Referring to FIG. 3D, the method may further include forming base die through-electrodes 33 in the holes H4. Each of the base die through-electrodes 33 may include a base die through-electrode plug, a base die through-electrode seed layer surrounding side surfaces of the base die through-electrode plug, and a base die through-electrode dielectric layer surrounding the side surfaces of the base die through-electrode seed layer. The base die through-electrode dielectric layer may be conformally formed on inner walls and bottom surfaces of the holes H4 by performing a Chemical Vapor Deposition (CVD) process or an Atomic Layer Deposition (ALD) process. The base die through-electrode dielectric layer may include an inorganic dielectric layer based on silicon oxide or silicon nitride. The base die through-electrode seed layer may include a metal or a metal compound that is formed by performing a CVD process or a PVD process. The base die through-electrode seed layer may be conformally formed on the base die through-electrode dielectric layer. In one embodiment, the base die through-electrode seed layer may include a lower base die through-electrode seed layer and an upper base die through-electrode seed layer. The lower base die through-electrode seed layer may include titanium (Ti), titanium nitride (TiN), or titanium tungsten (TiW). The upper base die through-electrode seed layer may include copper (Cu). The base die through-electrode plugs may be formed to completely fill the holes H4 over the base die through-electrode seed layer. The base die through-electrode plugs may include copper (Cu) that is formed by performing a plating process. The surfaces of the upper ends of the base die through-electrodes 33 may be exposed on the base die back-side passivation layer 32. The surfaces of the upper ends of the base die through-electrodes 33 and the upper surface of the base die back-side passivation layer 32 may be co-planar.

Referring to FIG. 3E, the method may further include forming base die back-side bump structures 37. Forming the base die back-side bump structures 37 may include forming an under-bump metallurgy (UBM) layer and a plating mask pattern on the base die back-side passivation layer 32 and the base die through-electrodes 33, forming bumps by performing a plating process, and removing the plating mask pattern. The bumps may include a bump metal and a bump capping layer. Each of the base die back-side bump structures 37 may include a base die back-side UBM layer 34 and base die back-side bump 35 and 36. The base die back-side bump 35 and 36 may include a base die back-side bump metal 35 and a base die back-side bump capping layer 36. The base die back-side UBM layer 34 may include a lower base die back-side UBM layer including titanium (Ti) or titanium tungsten (TiW) and an upper base die back-side UBM layer including copper (Cu). The base die back-side bump metals 35 may include a single metal layer or multiple metal layers including a metal, such as nickel (Ni) or copper (Cu). The base die back-side bump capping layers 36 may include an oxidation-resistant and corrosion-resistant metal, such as gold (Au).

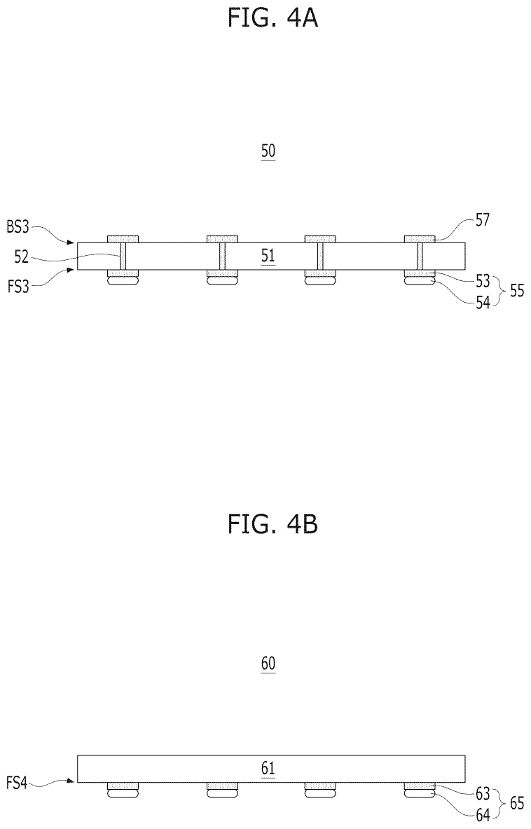

FIGS. 4A and 4B illustrate preparing a middle die 50 and a top die 60 in a method of manufacturing semiconductor die stack structures 101 and 102 in accordance with an embodiment of the present disclosure.

Referring to FIG. 4A, the method may further include preparing the middle die 50. The middle die 50 may include a middle die substrate 51, middle die through-electrodes 52 passing through the middle die substrate 51, middle die front-side bump structures 55 disposed on the front-side FS3 of the middle die substrate 51, and middle die back-side bump structures 57 disposed on the back-side BS3 of the middle die substrate 51. The middle die substrate 51 may include a middle die substrate 51, middle die circuit elements formed over the middle die substrate 51, middle die dielectric layers, a middle die front-side passivation layer, and a middle die back-side passivation layer. The middle die through-electrodes 52 may include a middle die through-electrode dielectric layer, a middle die through-electrode seed layer, and a middle die through-electrode plug. The structure of the middle die through-electrodes 52 may be referred to the structure of the bottom die through-electrodes 23. Each of the middle die front-side bump structures 55 may include a middle die front-side bump metal 53 and a middle die front-side bump solder 54. The middle die front-side bump metal 53 may include a metal, such as copper (Cu) or nickel (Ni). The middle die front-side bump solder 54 may include a solder material. Each of the middle die front-side bump structures 55 may further include a middle die front-side metal pad and a middle die front-side bump UBM layer that are disposed between the middle die substrate 51 and the middle die front-side bump metal 53, and between the middle die through-electrode 52 and the middle die front-side bump metal 53. The middle die front-side metal pad may correspond to the base die metal pad (12d in FIG. 1A). The middle-side front-side bump UBM layer may have the same structure as that of the base die back-side UBM layer (34 in FIG. 3E). For example, the middle die back-side bump structures 57 may include the same structure as those of the base die back-side bump structures (37 in FIG. 3E).

Referring to FIG. 4B, the method may further include preparing a top die 60. The top die 60 may include a top die substrate 61 and top die front-side bump structures 65 disposed on a front-side FS4 of the top die substrate 61. The top die substrate 61 may be substantially the same as the middle die substrate 51. The top die 60 may include top die circuit elements, top die dielectric layers, and a top die front-side passivation layer. Each of the top die front-side bump structures 65 may include a top die front-side bump metal 63 and a top die front-side bump solder 64. Each of the top die front-side bump structures 65 may further include a top die front-side metal pad and a top die front-side bump UBM layer. The top die front-side bump structures 65 may have the same structure as those of the middle die front-side bump structures (55 in FIG. 4A).

FIGS. 5A to 5E illustrate preparing a semiconductor die stack structure 101 in accordance with an embodiment of the present disclosure using the base-bottom die stack structure 30, the middle dies 50, and the top die 60.

Referring to FIGS. 5A and 5B, the method may further include stacking a plurality of the middle dies 50 (as seen by the arrows shown in FIG. 5A) and the top dies 60 over the base-bottom die stack structure 30, and molding the middle dies 50 and the top dies 60 with an encapsulant 90. The middle dies 50 and the top dies 60 may be stacked on the back-side of the base dies 10 of the base-bottom die stack structure 30. The encapsulant 90 may include an epoxy molding compound (EMC). A preliminary semiconductor die stack structure may be formed and fabricated by performing the described processes.

Referring to FIG. 5C, the method may include mounting the preliminary semiconductor die stack structure upside down over a wafer support system (WSS) and thinning the back-side of the bottom die substrate 21 (as shown by the arrows in FIG. 5C). The upper ends of the bottom die through-electrodes 23 may protrude upward from a thinned back-side BS2 of the bottom die substrate 21.

Referring to FIG. 5D, the method may further include forming a bottom die back-side passivation layer 72 on the back-side of the base-bottom die stack structure 30, that is, on the back-side BS2 of the thinned bottom dies 20. The bottom die back-side passivation layer 72 may include a silicon nitride-based dielectric layer which is formed by performing a CVD process. The method may further include planarizing the bottom die back-side passivation layer 72 to expose upper surfaces of the bottom die through-electrodes 23 by performing a planarization process, e.g., CMP. The upper surfaces of the bottom die through-electrodes 23 and the upper surface of the bottom die back-side passivation layer 72 may be co-planar.

Referring to FIG. 5E, the method may further include forming bottom die back-side bump structures 77. Each of the bottom die back-side bump structures 77 may include a bottom die back-side UBM layer 74 and a bottom die back-side bump 75 and 76. The bottom die back-side bump 75 and 76 may include a bottom die back-side bump metal 75 and bottom die back-side bump solders 76. For example, the method may include forming a UBM layer over the bottom die back-side passivation layer 72, forming a plating mask pattern, performing a plating process to form bumps, and removing the plating mask. The bottom die back-side UBM layer 74 may include a lower bottom die back-side UBM layer, e.g., titanium (Ti) or titanium nitride (TiW), and an upper bottom die back-side UBM layer, e.g., copper (Cu). The bottom die back-side bump metal 75 may include a single metal layer or multiple metal layers including a metal, e.g., copper (Cu) or nickel (Ni). According to one embodiment of the present disclosure, the bottom die back-side bump metal 75 may include a lower bottom die back-side bump metal layer including copper (Cu), a middle bottom die back-side bump metal layer including nickel (Ni), and an upper bottom die back-side bump metal layer including a copper (Cu) layer. Preliminary base die stack structures may be formed and fabricated by performing the described processes.

Referring to FIG. 5F, the method may further include manufacturing a plurality of semiconductor die stack structures 101 by dicing the preliminary base die stack structures. Each of the semiconductor die stack structures 101 may include the base-bottom die bonding structure 30 including the base die 10 and the bottom die 20 that are bonded face-to-face. For example, the base-bottom die bonding structure 30 may include the bottom die 20 bonded in a face-up manner and the base die 10 bonded in a face-down manner. The bottom die 20 and the base die 10 may be bonded by a hybrid bonding method.

The semiconductor die stack structure 101 may include the plurality of the middle dies 50 and one top die 60 that are stacked over the base-bottom die bonding structure 30. The middle dies 50 and the top die 60 may be stacked face-down on the back-side of the base die 10 of the base-bottom die bonding structure 30.

The bottom die 20 may be disposed in the lowermost portion of the semiconductor die stack structure 101. The bottom die 20 may include a bottom die substrate 21, a bottom die front-side passivation layer 22, a bottom die through-electrode 23, a bottom die front-side bonding dielectric layer 25, a bottom die front-side bonding pad structure 28, a bottom die back-side passivation layer 72 and a bottom die back-side bump structure 77. The bottom die 20 may not include active circuit elements. In other words, transistors may not be formed on the upper or lower surface of the bottom die substrate 21. The bottom die substrate 21 may include a silicon wafer. The bottom die front-side passivation layer 22 may be evenly disposed on the upper surface of the bottom die substrate 21. The bottom die back-side passivation layer 72 may be evenly disposed below the lower surface of the bottom die substrate 21. The bottom die front-side passivation layer 22 and the bottom die back-side passivation layer 72 may include a silicon nitride-based inorganic dielectric layer or a silicon oxide-based inorganic dielectric layer. The bottom die through-electrode 23 may vertically penetrate or pass through the bottom die substrate 21, the bottom die front-side passivation layer 22, and the bottom die back-side passivation layer 72. The bottom die through-electrode 23 may include copper (Cu). The upper surface of the bottom die through-electrode 23 may be exposed. The upper surface of the bottom die through-electrode 23 and the upper surface of the bottom die front-side passivation layer 22 may be co-planar. The bottom die front-side passivation layer 22 may surround side surfaces of the upper end of the bottom die through-electrode 23. The lower surface of the bottom die through-electrode 23 may be exposed. The lower surface of the bottom die through-electrode 23 and the lower surface of the bottom die back-side passivation layer 72 may be co-planar. The bottom die back-side passivation layer 72 may surround the side surface of the lower end of the bottom die through-electrode 23. The bottom die front-side bonding dielectric layer 25 and the bottom die front-side bonding pad structure 28 may be disposed over the bottom die front-side passivation layer 22. The bottom die front-side bonding dielectric layer 25 may cover the side surface of the bottom die front-side bonding pad structure 28. The upper surface of the bottom die front-side bonding dielectric layer 25 and the upper surface of the bottom die front-side bonding pad structure 28 may be co-planar. The bottom die front-side passivation layer 22 may include at least one of a silicon oxide-based inorganic dielectric layer, a silicon nitride-based inorganic dielectric layer, or a silicon carbonitride-based inorganic dielectric layer. The bottom die front-side bonding pad structure 28 may include a bottom die front-side bonding pad seed layer 26 and a bottom die front-side bonding pad metal 27. The bottom die front-side bonding pad seed layer 26 may include a lower bottom die front-side bonding pad seed layer including at least one of titanium (Ti), titanium nitride (TiN), or titanium tungsten (TiW), and an upper bottom die front-side bonding pad seed layer including copper (Cu). The bottom die front-side bonding pad metal 27 may include copper (Cu). The bottom die front-side bonding pad seed layer 26 may surround the bottom die front-side bonding pad metal 27 in a U-shape or a bowl shape. The bottom die front-side bonding pad structure 28 may be electrically connected to the bottom die through-electrode 23. The bottom die back-side bump structure 77 may be disposed below the lower surface of the bottom die back-side passivation layer 72. The bottom die back-side bump structure 77 may be electrically connected to the bottom die through-electrode 23. The bottom die back-side bump structure 77 may include a bottom die back-side UBM layer 74 and a bottom die back-side bump 75 and 76. The bottom die back-side bump 75 and 76 may include a bottom die back-side bump metal 75 and a bottom die back-side bump solder 76. The bottom die back-side UBM layer 74 may be directly disposed below the lower surface of the bottom die back-side passivation layer 72. The bottom die back-side bump metal 75 may be disposed below the bottom die back-side UBM layer 74. The bottom die back-side bump solder 76 may be disposed the below bottom die back-side bump metal 75.

The base die 10 may be stacked over the bottom die 10 in a face-down manner. In other words, the active surface, i.e., the front-side of the base die 10 may be disposed downward to face the bottom by 20. The base die 10 may include a base die substrate 11, base die circuit elements 12, a base die inter-layer dielectric layer 13, a base die front-side bonding dielectric layer 15, a base die front-side bonding pad structure 18, a base die back-side passivation layer 32, a base die through-electrode 33, and a base die back-side bump structure 37. The base die front-side bonding pad structure 18 may include a base die front-side bonding pad seed layer 16 and a base die front-side bonding pad metal 17. The base die back-side bump structure 37 may include a base die back-side UBM layer 34 and a base die back-side bump 35 and 36. The base die back-side bump 35 and 36 may include a base die back-side bump metal 35 and a base die back-side bump capping layer 36.

The base die substrate 11 may include a silicon wafer. The base die circuit elements 12 may include a base die transistor 12a, a base die metal interconnection 12b, a base die metal via 12c, a base die metal pad 12d. For example, base die circuit elements 12 may include memory peripheral logic circuits. The base die transistor 12a may be disposed on the active side of the base die substrate 11. The base die metal interconnection 12b may transfer electrical signals by extending in a horizontal direction. The base die metal interconnection 12b may be coupled to the base die through-electrode 33. The base die metal via 12c may extend in a vertical direction to electrically connect the base die substrate 11, the transistor 12a, the base die metal interconnection 12b, and the base die metal pad 12d. The base die inter-layer dielectric layer 13 may cover the base die circuit elements 12. The base die inter-layer dielectric layer 13 may include at least one of a silicon oxide-based dielectric layer or a silicon nitride-based dielectric layer. The base die metal pad 12d may be disposed adjacent to the upper surface of the base die inter-layer dielectric layer 13. For example, the base die inter-layer dielectric layer 13 may expose a portion of the surface of the base die metal pad 12d. The base die front-side bonding dielectric layer 15 may be disposed below the non-exposed surfaces of the base die inter-layer dielectric layer 13 and the base die metal pad 12d. The base die front-side bonding dielectric layer 15 may include at least one of a silicon oxide-based inorganic dielectric layer, a silicon nitride-based inorganic dielectric layer, or a silicon carbonitride-based inorganic dielectric layer. The base die front-side bonding dielectric layer 15 and the bottom die front-side bonding dielectric layer 25 may be directly in contact with each other. The base die front-side bonding pad structure 18 may include a base die front-side bonding pad seed layer 16 and a base die front-side bonding pad metal 17. The base die front-side bonding pad seed layer 16 may surround a lower surface (front-side) and side surfaces of the base die front-side bonding pad metal 17 in a (reverse) U-shape, an n-shape, or a (reverse) bowl shape. The base die front-side bonding pad seed layer 16 may include a lower base die front-side bonding pad seed layer including at least one of titanium (Ti), titanium nitride (TiN), or titanium tungsten (TiW), and an upper base die front-side bonding pad seed layer including copper (Cu). The base die front-side bonding pad metals 17 may include a metal, e.g., copper (Cu) or nickel (Ni). The base die front-side bonding pad structure 18 and the bottom die front-side bonding pad structure 28 may be directly in contact with each other. The base die back-side passivation layer 32 may be conformally disposed on the back-side of the base die substrate 11. The base die back-side passivation layer 32 may include a silicon oxide-based inorganic dielectric layer or a silicon nitride-based inorganic dielectric layer. The base die through-electrode 33 may completely pass through or penetrate the base die substrate 11 and the base die back-side passivation layer 32 and partially pass through or penetrate the base die inter-layer dielectric layer 13 to be electrically connected to the base die metal interconnection 12b of the base die circuit elements 12. The base die through-electrode 33 may include copper (Cu). The base die back-side bump structure 37 may be disposed over the base die back-side passivation layer 32. The base die back-side bump structure 37 may be electrically connected to the base die through-electrode 33. The base die back-side UBM layer 34 may include a lower base die back-side UBM layer including titanium (Ti) or titanium tungsten (TiW), and an upper base die back-side UBM layer including copper (Cu). The base die back-side bump metals 35 may include a single metal layer or multiple metal layers of a metal, e.g., nickel (Ni) or copper (Cu). The base die back-side bump capping layers 36 may include an oxidation-resistant and corrosion-resistant metal, e.g., gold (Au). The base die 10 and the bottom die 20 may be stacked and bonded by a hybrid bonding method.

The middle dies 50 may be stacked over the base die 10. Each of the middle dies 50 may include a middle die substrate 51, a middle die through-electrode 52, a middle die front-side bump structure 55, and a middle die back-side bump structure 57. The middle die front-side bump structure 55 may include a middle die front-side bump metal 53 and a middle die front-side bump solder 54. The middle dies 50 may be memory dies. For example, the middle dies 50 may include a memory core circuit. The middle die substrate 51 may include a silicon wafer. The middle die through-electrode 52 may pass through or penetrate the middle die substrate 51 vertically to electrically connect the middle die front-side bump structure 55 to the middle die back-side bump structure 57 to each other. The middle die through-electrode 52 may include a conductive metal, e.g., copper (Cu). A middle die front-side bump structure 55 may be disposed below the lower surface (front-side) of the middle die substrate 51. The middle die front-side bump structure 55 may include a middle die front-side bump metal 53 and a middle die front-side bump solder 54. The middle die front-side bump metal 53 and the middle die bump solder 54 may include a solder material. The base die back-side bump structure 37 of the base die 10 and the front-side bump structure 55 of the lowermost middle die 50 may be in contact with and bonded to each other. For example, the base die back-side bump capping layer 36 of the base die back-side bump structure 37 of the base die 10 and the middle die front-side bump metal 53 of the lowermost middle die 50 may be coupled by the middle die front-side bump solder 54. The middle die front-side bump structures 55 and the middle die back-side bump structures 57 of the stacked middle dies 50 may be in contact with and bonded to each other. The middle die front-side metal pad may have the same structure as that of the base die metal pad 12d. For example, the middle die front-side metal pad may be disposed adjacent to the upper surface of the middle die inter-layer dielectric layer over the middle die substrate 51. The middle die front-side bump UBM layer may have the same structure as that of the base die back-side UBM layer 34. For example, the middle die back-side bump structures 57 may include the same structure as that of the base die back-side bump structures 37.

The top die 60 may include a top die substrate 61 and top die front-side bump structures 65. The top die substrate 61 may have the same structure as that of the middle die substrate 51. For example, the top die substrate 61 may also be memory dies. Accordingly, the top die 60 may also include a memory core circuit. The top die front-side bump structure 65 may be disposed below the lower surface (front-side) of the top die substrate 61. The top die front-side bump structure 65 may include a top die front-side bump metal 63 and a top die front-side bump solder 64. The top die front-side bump structure 65 may be the same as that of the middle die front-side bump structure 55. The top die front-side bump structures 65 of the top die 60 may be directly in contact with and bonded to the middle die back-side bump structures 57 of the middle die 50 that are stacked on the uppermost portion of the middle dies 50.

The semiconductor stack structure 101 may further include an encapsulant 90 surrounding the middle dies 50 and the top die 60 over the base die back-side passivation layer 32 of the base die 10. The encapsulant 90 may include an epoxy molding compound. The base die 10 and the bottom die 20 may have the same horizontal width W1. The middle dies 50 and the top die 60 may have the same horizontal width W2. The horizontal width W1 of the base die 10 and the bottom die 20 may be greater than the horizontal width W2 of the middle dies 50 and the top die 60. Accordingly, the molding material 90 may be formed over the base die back-side passivation layer 32 over the back-side BS1 of the base die 20 to encapsulate the side surfaces of the middle dies 50 and the top die 60. Both side surfaces of the base die 10, both side surfaces of the bottom die 20, and both side surfaces of the molding material 90 may be vertically co-planar.

FIGS. 6A to 6G illustrate a method of manufacturing a semiconductor die stack structure 102 in accordance with another embodiment of the present disclosure using the base-bottom die stack structure 30, the middle dies 50, and the top die 60 in accordance with an embodiment of the present disclosure.

Referring to FIG. 6A, the method may further include performing the processes described with reference to FIGS. 5A to 5C, forming a preliminary bottom die back-side pad UBM layer 78p over the bottom die back-side passivation layer 72, forming a plating mask pattern M1 over the preliminary bottom die back-side pad UBM layer 78p, and forming bottom die back-side pads 79. The plating mask pattern M1 may have holes H5 exposing the upper ends of the bottom die through-electrodes 23. The bottom die back-side pads 79 may be formed over the preliminary bottom die back-side pad UBM layer 78p to fill the lower portions of the holes H5. The bottom die back-side pads 79 may include copper (Cu) or nickel (Ni) formed by performing a plating process.

Referring to FIG. 6B, the method may further include removing the plating mask pattern M1 and removing the exposed preliminary bottom die back-side pad UBM layer 78p. A portion of the preliminary bottom die back-side pad UBM layer 78p may form the remaining bottom die back-side pad UBM layer 78 below the bottom die back-side pads 79. A portion of the upper surface of the bottom die back-side passivation layer 72 may be exposed.

Referring to FIG. 6C, the method may further include forming a bottom die top back-side passivation layer 73 over the bottom die back-side passivation layer 72. The bottom die top back-side passivation layer 73 may include an inorganic dielectric material, such as silicon oxide or silicon nitride, and/or a polymeric organic material, such as polyimide-isoindro-quinazoline dione (PIQ). The bottom die top back-side passivation layer 73 may have holes H6 exposing the surfaces of the bottom die back-side pads 79.

Referring to FIG. 6D, the method may further include forming a preliminary bottom die back-side UBM layer 74p over the exposed surfaces of the bottom die top back-side passivation layer 73 and the bottom die back-side pads 79, and forming a plating mask pattern M2 having holes H7 vertically overlapping with the bottom die back-side pads 79.

Referring to FIG. 6E, the method may include forming the bottom die back-side bump metals 75 by performing a plating process. The bottom die back-side bump metals 75 may have a multi-layer structure. For example, the bottom die back-side bump metals 75 may include a lower bottom die back-side bump metal 75a, a middle bottom die back-side bump metal 75b, and an upper bottom die back-side bump metal 75c, respectively. According to one embodiment of the present disclosure, the lower bottom die back-side bump metal 75a and the upper bottom die back-side bump metal 75c may include the same metal. For example, the lower bottom die back-side bump metal 75a and the upper bottom die back-side bump metal 75c may include copper (Cu). The middle bottom die back-side bump metal 75b may include a metal that is different from the lower bottom die back-side bump metal 75a and the upper bottom die back-side bump metal 75c. For example, the middle bottom die back-side bump metal 75b may include nickel (Ni). In an embodiment, a multi-layer bump structure including a copper (Cu) layer and a nickel (Ni) layer may be suitable for forming a bump structure having a sufficient thickness. In an embodiment, nickel (Ni) may provide hardness and anti-corrosion characteristics for the bump structure.

Referring to FIG. 6F, the method may further include forming the bottom die back-side bump solders 76 over the bottom die back-side bump metals 75, removing the plating mask pattern M2, and forming the preliminary bottom die back-side UBM layer 74p exposed below the plating mask pattern M2. The bottom die back-side bump structures 77 including the bottom die back-side UBM layers 74 and the bottom die back-side bump 75 and 76, respectively, may be formed. The bottom die back-side bump 75 and 76 may include a bottom die back-side bump metal 75 and a bottom die back-side bump solder 76.

Referring to FIG. 6G, the method may further include manufacturing the semiconductor die stack structure 102 by performing a singulation process.

The semiconductor die stack structure 102 may include a plurality of middle dies 50 and a top die 60 that are stacked over the base-bottom die bonding structure 30. The middle dies 50 and the top die 60 may be stacked face-down on the back-side of the base die 10 of the base-bottom die bonding structure 30.

The bottom die 20 may be disposed in the lowermost portion of the semiconductor die stack structure 102. The bottom die 20 may include a bottom die substrate 21, a bottom die front-side passivation layer 22, a bottom die through-electrode 23, a bottom die front-side bonding dielectric layer 25, a bottom die front-side bonding pad structure 28, a bottom die back-side passivation layer 72, a bottom die top back-side passivation layer 73, a bottom die back-side pad UBM layer 78, a bottom die back-side pad 79, and a bottom die back-side bump structure 77.

The bottom die top back-side passivation layer 73 may be disposed below the lower surface of the bottom die back-side passivation layer 72. The bottom die top back-side passivation layer 73 may include an inorganic dielectric material, such as silicon oxide or silicon nitride, and/or a polymeric organic material, such as polyimide-isoindro-quinazoline dione (PIQ). The bottom die top back-side passivation layer 73 may surround the sides of the bottom die back-side pad UBM layer 78 and the bottom die back-side pad 79.

The bottom die back-side pad UBM layer 78 and the bottom die back-side pad 79 may be disposed below the lower surface of the bottom die back-side passivation layer 72. The bottom die back-side pad UBM layer 78 and the bottom die back-side pad 79 may be electrically connected to the bottom die through-electrode 23. The bottom die back-side pad UBM layer 78 may include a lower bottom die back-side pad UBM layer including titanium (Ti) or titanium tungsten (TiW) and an upper bottom die back-side pad UBM layer including copper (Cu). The bottom die back-side pad 79 may include copper (Cu) or nickel (Ni). According to one embodiment of the present disclosure, the bottom die back-side pads 79 may include a copper (Cu) layer and a nickel (Ni) layer that is formed over the copper (Cu) layer. According to one embodiment of the present disclosure, the bottom die back-side pads 79 may include a copper (Cu) layer and a capping metal layer over the copper (Cu) layer. The capping metal layer may include an oxidation-resistant or corrosion-resistant metal. For example, the capping metal layer may include gold (Au).

The bottom die back-side bump structure 77 may be disposed below the lower surfaces of the bottom die back-side pad 79 and the bottom die back-side top passivation layer 73. The bottom die back-side bump structure 77 may be in contact with the bottom die back-side pad 79. The bottom die back-side bump structure 77 may include a bottom die back-side UBM layer 74 and a bottom die back-side bump 75 and 76. The bottom die back-side bump 75 and 76 may include a bottom die back-side bump metal 75 and a bottom die back-side bump solder 76. The bottom die back-side UBM layer 74 may include a lower bottom die back-side UBM layer, such as titanium (Ti) or titanium nitride (TiW), and an upper bottom die back-side UBM layer, such as copper (Cu). The bottom die back-side bump metals 75 may include a single metal layer or multiple metal layers including a metal, such as copper (Cu) or nickel (Ni). According to one embodiment of the present disclosure, the bottom die back-side bump metals 75 may include a lower bottom die back-side bump metal layer 75a including copper (Cu), a middle bottom die back-side bump metal layer 75b including nickel (Ni), and an upper bottom die back-side bump metal layer 75c including copper (Cu). The bottom die back-side bump solder 76 may be disposed below the bottom die back-side bump metal 75. The bottom die back-side bump solder 76 may include a solder material. The constituent elements of the reference numerals that are not described may be understood with reference to FIG. 5F.

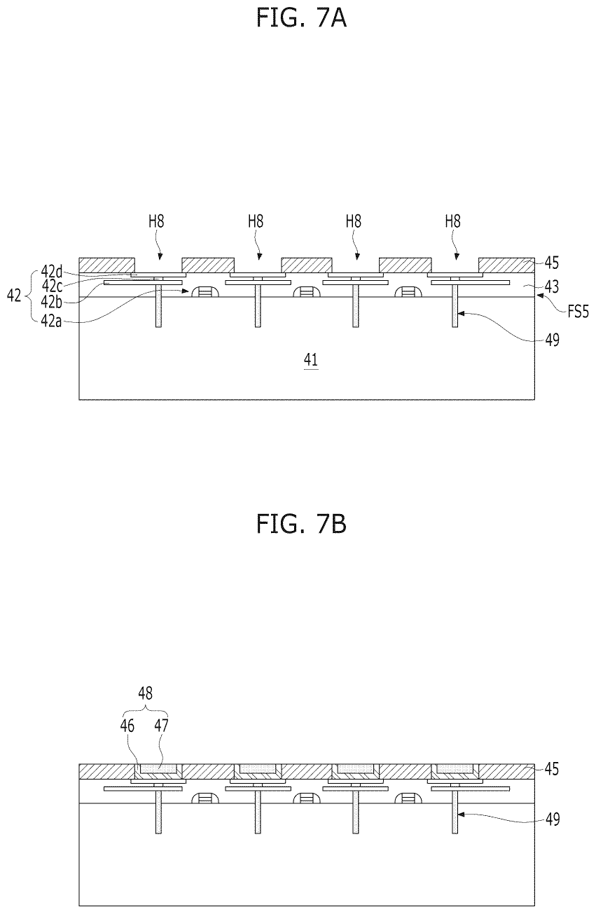

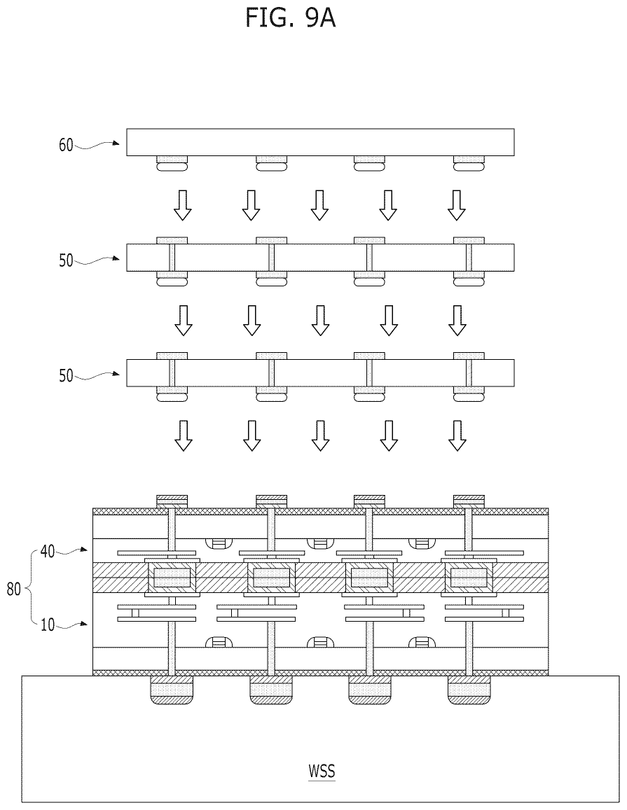

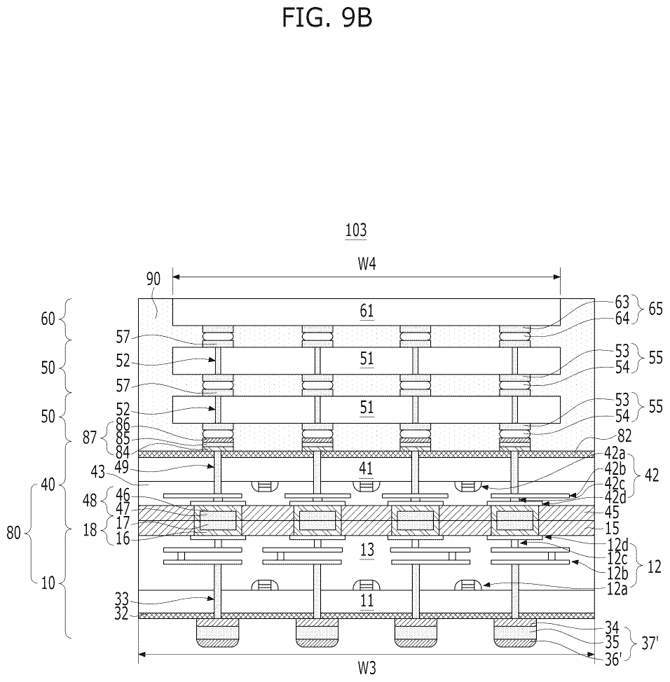

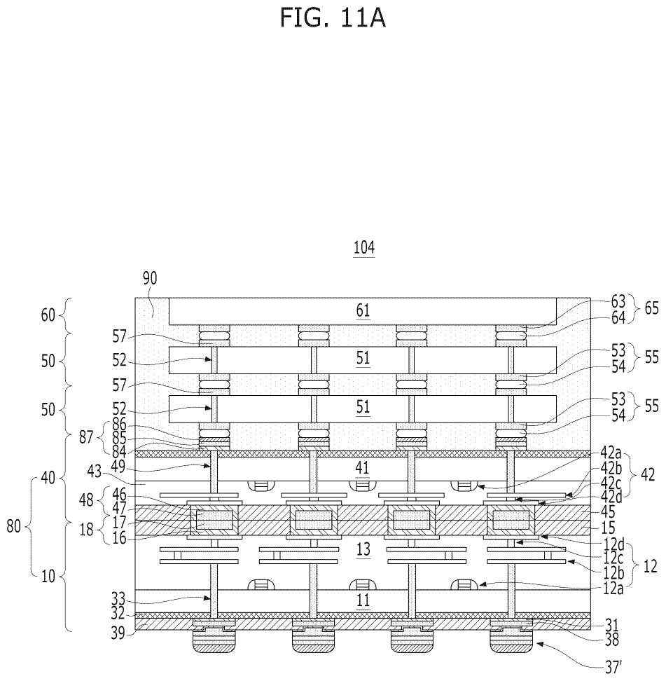

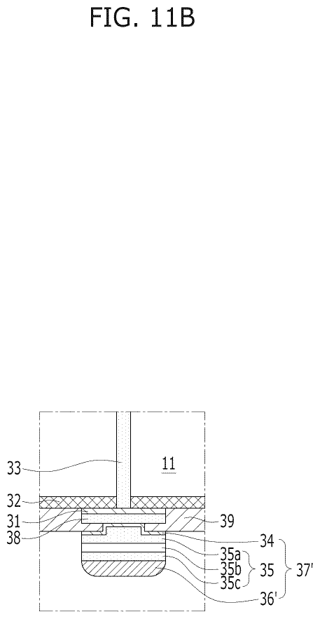

FIGS. 7A to 10F illustrate methods of manufacturing semiconductor die stack structures (103 in FIG. 9B and 104 in FIG. 11A) in accordance with embodiments of the present disclosure. Referring to FIGS. 7A to 10F, the methods of manufacturing semiconductor die stack structures (103 in FIG. 9B and 104 in FIG. 11A) may include preparing a base die 10, preparing a bottom die 40, forming and preparing a base-bottom die stack structure 80 by bonding the base die 10 and the bottom die 40, preparing middle dies 50 and a top die 60, stacking the middle dies 50 and the top die 60 over the base-bottom die stack wafer 80, and performing a dicing process.

FIGS. 7A and 7B illustrate manufacturing and preparing the bottom die 40 in the method of manufacturing a semiconductor die stack structure (103 in FIG. 9B) in accordance with an embodiment of the present disclosure. Referring to FIG. 7A, the method may include forming bottom die circuit elements 42, a bottom die inter-layer dielectric layer 43, and bottom die through-electrodes 49 over the front-side (active surface) FS5 of the bottom die substrate 41 of a wafer state, and forming a bottom die front-side bonding dielectric layer 45 over the bottom die circuit elements 42 and the bottom die inter-layer dielectric layer 43. The bottom die substrate 41 may include a silicon wafer. The bottom die circuit elements 42 may include bottom die transistors 42a, bottom die metal interconnections 42b, bottom die metal vias 42c, and bottom die metal pads 42d. According to one embodiment of the present disclosure, the bottom die circuit elements 42 may include memory cell circuits, e.g., memory core circuits, such as cell banks and decoder circuit blocks. The bottom die through-electrodes 49 may completely pass through the bottom die inter-layer dielectric layer 43 and partially pass through the bottom die substrate 41. For example, first ends of the bottom die through-electrodes 49 may be in contact with some of the bottom die metal interconnections 42b, and second ends of the bottom die through-electrodes 49 may be disposed in the bottom die substrate 41. The bottom die front-side bonding dielectric layer 45 may include an inorganic dielectric material based on silicon oxide, silicon nitride, or silicon carbonitride. The bottom die front-side bonding dielectric layer 45 may include silicon carbonitride. The bottom die front-side bonding dielectric layer 45 may have holes H8 exposing the surfaces of the bottom die metal pads 42d.

Referring to FIG. 7B, the method may further include forming bottom die front-side bonding pad structures 48 on the surfaces of the bottom die metal pads 42d exposed in the holes H8. The bottom die front-side bonding pad structures 48 may be vertically aligned with the bottom die metal pads 42d and the bottom die through-electrodes 49 over the bottom die metal pads 42d, respectively. Each of the bottom die front-side bonding pad structures 48 may include a bottom die front-side bonding pad seed layer 46 and a bottom die front-side bonding pad metal 47. Each bottom die front-side bonding pad seed layer 46 may surround the bottom and side surfaces of each bottom die front-side bonding pad metal 47 in a U-shape.

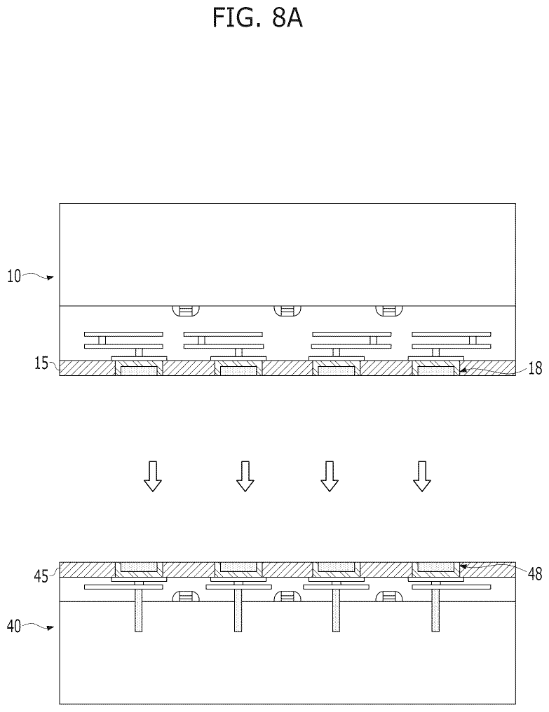

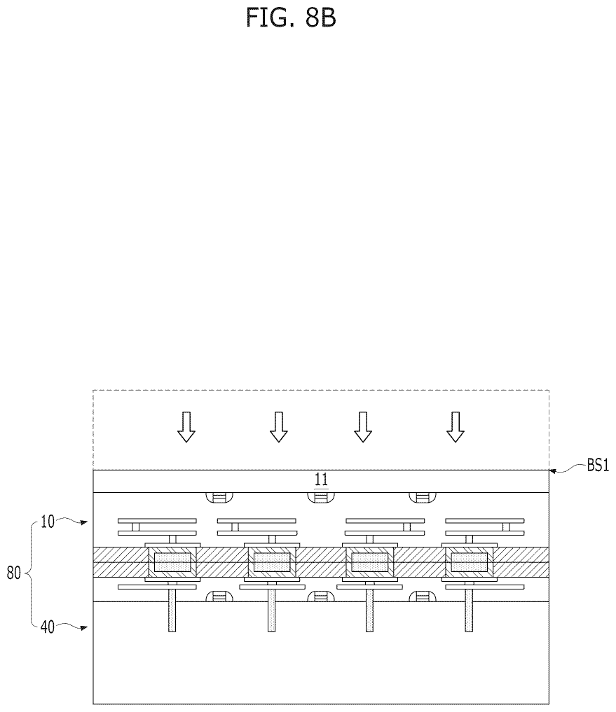

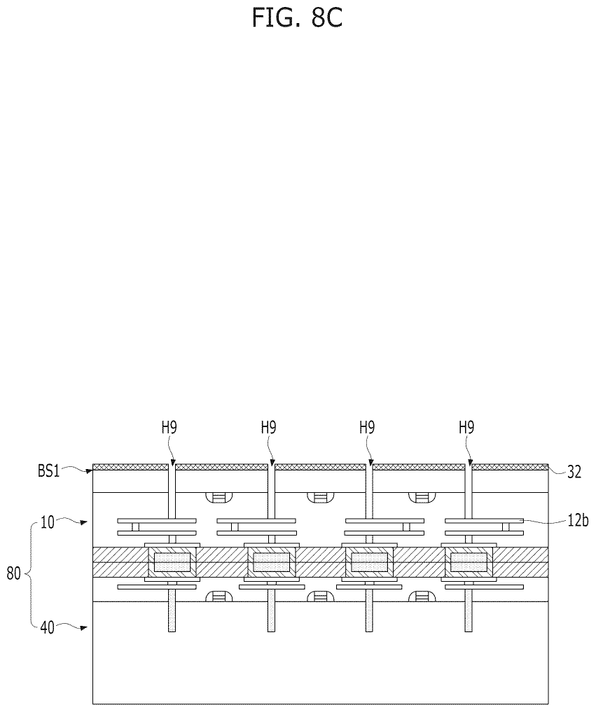

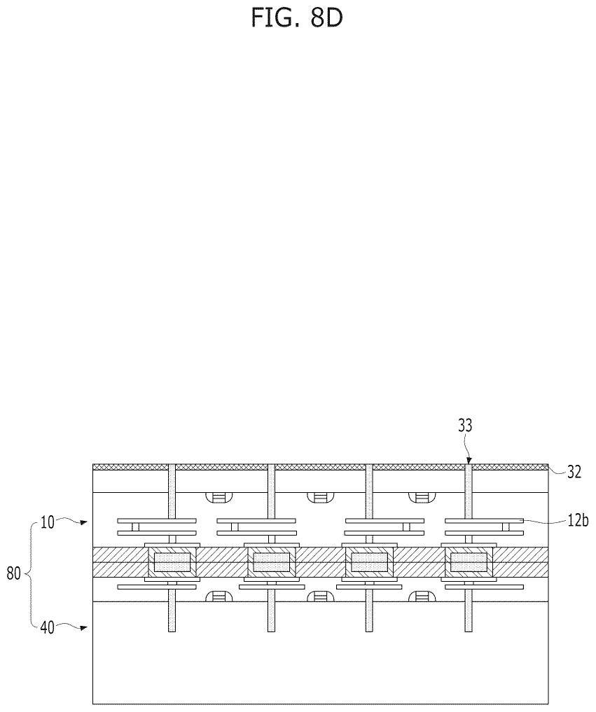

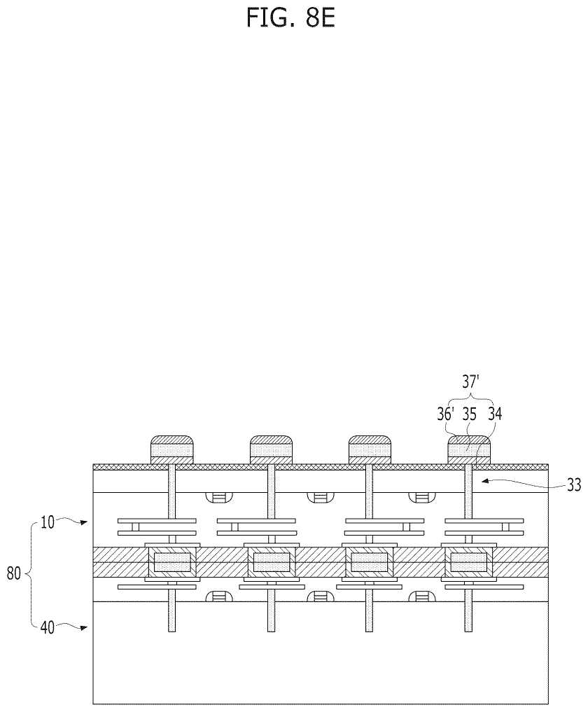

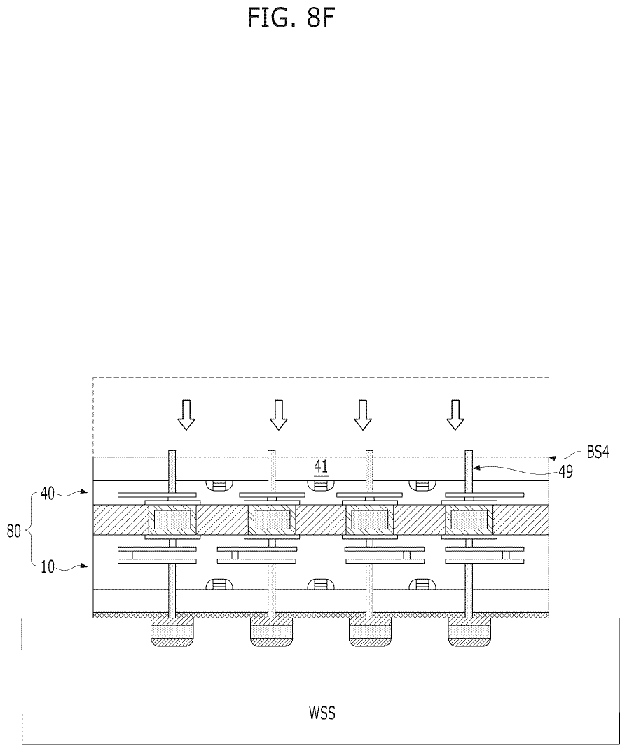

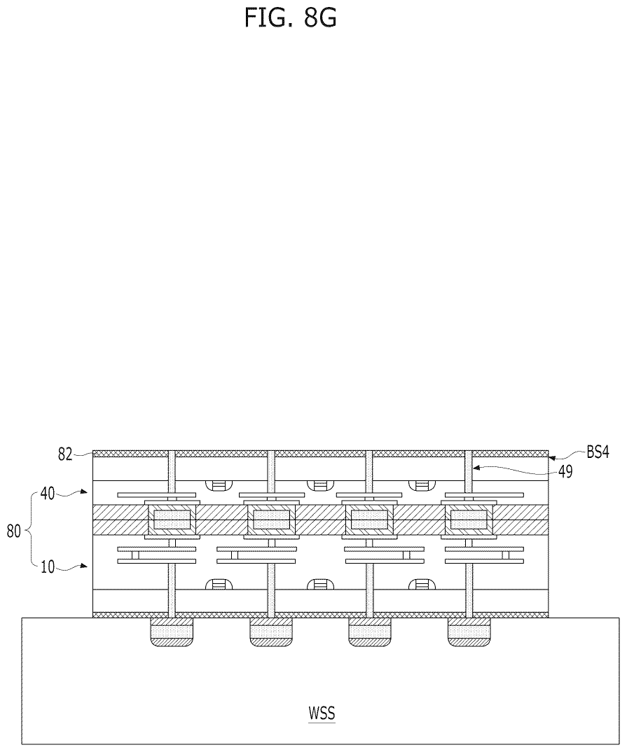

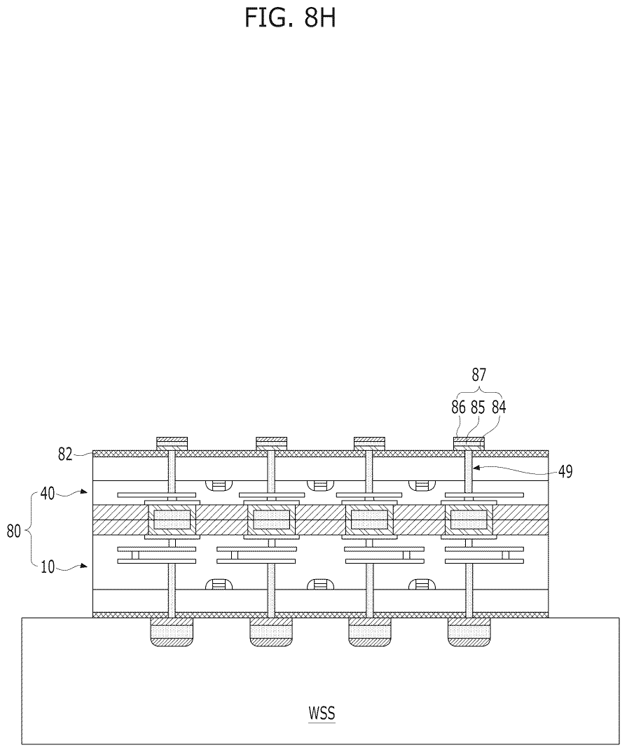

FIGS. 8A to 8H illustrate forming and preparing a plurality of base-bottom die stack structure 80 by bonding the base die 10 and the bottom die 40 (as indicated by the arrows in FIG. 8A) in a method of manufacturing a semiconductor die stack structure 103 in accordance with an embodiment of the present disclosure.

Referring to FIG. 8A, the method may further include bonding a plurality of base dies 10 and a plurality of bottom dies 40 in a wafer-to-wafer manner. For example, the method may further include placing the bottom dies 40 face-up, and bonding the base dies 10 which are face-down with the bottom dies 40. The base dies 10 and the bottom dies 40 may be coupled to each other by a hybrid bonding method. Each of the base die front-side bonding pad structures 18 and each of the bottom die front-side bonding pad structures 48 may be directly in contact with and bonded to each other by heat. The base die front-side bonding dielectric layer 15 and the bottom die front-side bonding dielectric layer 45 may be directly in contact with and bonded to each other by a surface activation treatment.

Referring to FIG. 8B, the method may further include thinning the back-side (inactive surface) of the base die substrate 11 of the base-bottom die stack structure 80 by performing a back-grinding process (as indicated by the arrows shown).

Referring to FIGS. 8C (and 8B), the method may further include forming a base die back-side passivation layer 32 over the thinned back-side BS1 of the base die substrate 11 and forming holes H9. The holes H9 may vertically penetrate the thinned base die substrate 11 to selectively and partially expose the base die metal interconnections 12b.

Referring to FIG. 8D, the method may further include forming base die through-electrodes 33 in the holes H9.

Referring to FIG. 8E, the method may further include forming base die back-side bump structures 37′. The method may further include forming the base die back-side UBM layers 34 and the base die back-side bumps 35 and 36′ so that the base die back-side bump structures 37′ are coupled to the base die through-electrodes 33 over the base die back-side passivation layer 32. Forming the base die back-side bumps 35 and 36′ may include forming base die back-side bump metals 35 and base die back-side bump solders 36′.

Referring to FIG. 8F, the method may further include mounting the base-bottom die stack structure 80 over a wafer support system WSS so that the base dies 10 are disposed below, and performing a back-grinding process (as indicated by the arrows) to thin the back-side of the bottom die 40 and to expose the ends of the bottom die through-electrodes 49.

Referring to FIG. 8G, the method may further include forming a bottom die back-side passivation layer 82 over the thinned back-side BS4 of the bottom die 40, and co-planarizing the upper surface of the bottom die back-side passivation layer 82 and the upper ends of the bottom die through-electrodes 49. The bottom die back-side passivation layer 82 may include a dielectric material including silicon nitride or silicon oxide.

Referring to FIG. 8H, the method may further include forming bottom die back-side bump structures 87 over the upper surface of the bottom die back-side passivation layer 82 and the upper ends of the bottom die through-electrodes 49. Each of the bottom die back-side bump structures 87 may include a bottom die back-side UBM layer 84 and a bottom die back-side bump 85 and 86. The bottom die back-side bump 85 and 86 may include a bottom die back-side bump metal 85 and a bottom die back-side bump capping layer 86. The bottom die back-side UBM layer 84 may include a lower bottom die UBM layer including titanium (Ti) or titanium tungsten (TiW) and an upper bottom die UBM layer including copper (Cu). The bottom die back-side bump metal 85 may include nickel (Ni) and/or copper (Cu). The bottom die back-side bump capping layer 86 may include an oxidation-resistant metal, such as gold (Au).

FIG. 9A illustrates manufacturing a semiconductor die stack structure 103 using a base-bottom die stack structure 80, middle dies 50, and a top die 60 in accordance with an embodiment of the present disclosure.

Referring to FIG. 9A, the method may further include stacking a plurality of middle dies 50 and a top die 60 over the base-bottom die stack structure 80 in a chip-to-wafer manner as indicated by the arrows.

Referring to FIG. 9B, the method may further include forming a preliminary base-bottom die stack structure by molding the middle dies 50 and the top dies 60 with an encapsulant 90, and manufacturing the semiconductor die stack structures 103 by dicing the preliminary base-bottom die stack structure. The semiconductor die stack structure 103 may include a plurality of middle dies 50 and the top die 60 that are stacked over the base die 10 and the bottom die 40 that are bonded face-to-face. The semiconductor die stack structure 103 may include a bottom die 40, middle dies 50, and a top die 60 that are directly stacked in a face-down manner over the base die 10 which is disposed in a face-up manner. The base die 10 and the bottom die 40 may have the same horizontal width W3. The middle dies 50 and the top die 60 may have the same horizontal width W4. The horizontal width W3 of the base die 10 and the bottom die 40 may be greater than the horizontal width W4 of the middle dies 50 and the top die 60. Accordingly, the molding material 90 may be formed over the bottom die back-side passivation layer 82 on the back-side BS5 of the bottom die 40 to encapsulate the side surfaces of the middle dies 50 and the top die 60. Both side surfaces of the base die 10, both side surfaces of the bottom die 40, and both side surfaces of the molding material 90 may be vertically co-planar.

The base die 10 may be disposed in the lowermost portion of the semiconductor stack structure 103 in a face-up manner. The base die 10 may include a base substrate 11, base die circuit elements 12, a base die inter-layer dielectric layer 13, a base die front-side bonding dielectric layer 15, a base die front-side bonding pad structure 18, a base die back-side passivation layer 32, a base die through-electrode 33, and a base die back-side bump structure 37′. The base die front-side bonding pad structure 18 may include a base die front-side pad barrier layer 16 and a base die front-side bonding metal 17. The base die back-side bump structure 37′ may include a base die back-side UBM layer 34 and a base die back-side bump 35 and 36. The base die back-side bump 35 and 36 may include a base die back-side bump metal 35 and a base die back-side bump solder 36′. The base die back-side bump solder 36′ may include a solder material.

The bottom die 40 may include a bottom die substrate 41, bottom die circuit elements 42, a bottom die inter-layer dielectric layer 43, a bottom die front-side passivation layer 45, a bottom die front-side bonding pad structure 48, a bottom die through-electrode 49, a bottom die back-side passivation layer 82, and a bottom die back-side bump structure 87. The bottom die front-side bonding structure 45 may include a bottom die front-side bonding pad barrier layer 46 and a bottom die front-side bonding pad metal 47. The bottom die back-side bump structure 87 may include a bottom die back-side UBM layer 84 and a bottom die back-side bump 84 and 85. The bottom die back-side bump 84 and 85 may include a bottom die back-side bump metal 85 and a bottom die back-side capping layer 85. The bottom die circuit elements 42 may include a bottom die transistor 42a, a bottom die metal interconnection 42b, a bottom die metal via 42c, and a bottom die metal pad 42d. For example, the bottom die circuit elements 42 may include a memory cell bank, a memory core circuit, or a decoder circuit block. The bottom die transistor 42a may be disposed on the active side of the bottom die substrate 41. The bottom die metal interconnection 42b may transfer electrical signals by extending in a horizontal direction. The bottom die metal interconnection 42b may be coupled to the bottom die through-electrode 49. The bottom die metal via 42c may extend in a vertical direction to electrically connect the bottom die substrate 41, the bottom die transistor 42a, the bottom die metal interconnection 42b, and the bottom die metal pad 42d to each other. The bottom die inter-layer dielectric layer 43 may cover the bottom die circuit elements 42. The bottom die inter-layer dielectric layer 43 may include a silicon oxide-based dielectric material or silicon nitride-based dielectric material. The bottom die metal pad 42d may be disposed adjacent to the upper surface of the bottom die inter-layer dielectric layer 43. For example, the bottom die inter-layer dielectric layer 43 may expose a portion of the surface of the bottom die metal pad 42d. The bottom die front-side bonding dielectric layer 45 may be disposed below the non-exposed surfaces of the bottom die inter-layer dielectric layer 43 and the bottom die metal pad 42d. The bottom die through-electrode 49 may completely pass through vertically or penetrate the bottom die substrate 41 and the bottom die back-side passivation layer 82 and partially pass through vertically or penetrate the bottom die inter-layer dielectric layer 43 to electrically connect the bottom die metal interconnection 42b to the bottom die back-side bump structure 87. The bottom die through-electrode 49 may include a metal, such as copper (Cu). The bottom die back-side passivation layer 82 may be disposed on the inactive surface (back-side) of the bottom die substrate 41. The bottom die back-side passivation layer 82 may surround the side surfaces of the upper end of the bottom die through-electrode 49. The bottom die back-side UBM layer 84 may include a lower bottom die UBM layer including titanium (Ti) or titanium tungsten (TiW) and an upper bottom die UBM layer including copper (Cu). The bottom die back-side bump metals 85 may include nickel (Ni) and/or copper (Cu). The bottom die back-side bump capping layers 86 may include an oxidation-resistant metal, such as gold (Au).

The base die 10 and the bottom die 40 may be bonded by a hybrid bonding method. The base die front-side bonding pad structure 18 of the base die 10 and the bottom die front-side bonding pad structure 48 of the bottom die 40 may be directly in contact with each other. The base die front-side bonding dielectric layer 15 of the base die 10 and the bottom die front-side bonding pad structure 48 of the bottom die 40 may be directly in contact with each other. The middle die front-side bump structure 55 of the middle die 50 and the bottom die back-side bump structure 87 of the bottom die 40 may be bonded. The constituent elements of the reference numerals that are not described may be understood with reference to FIGS. 5F and 6G.

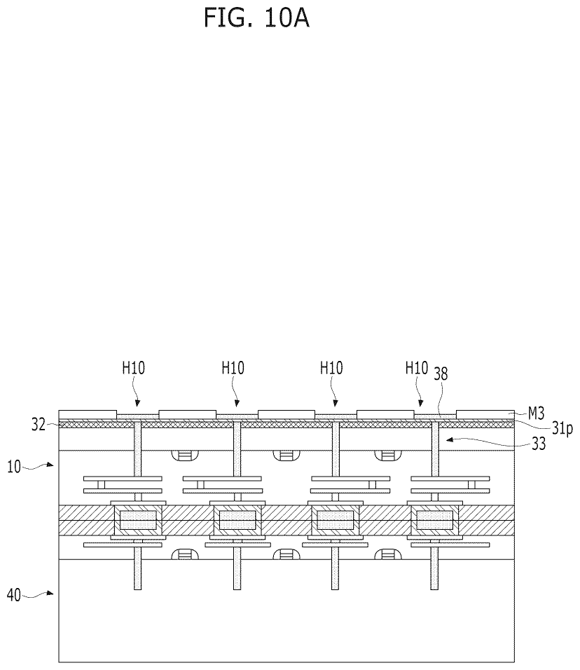

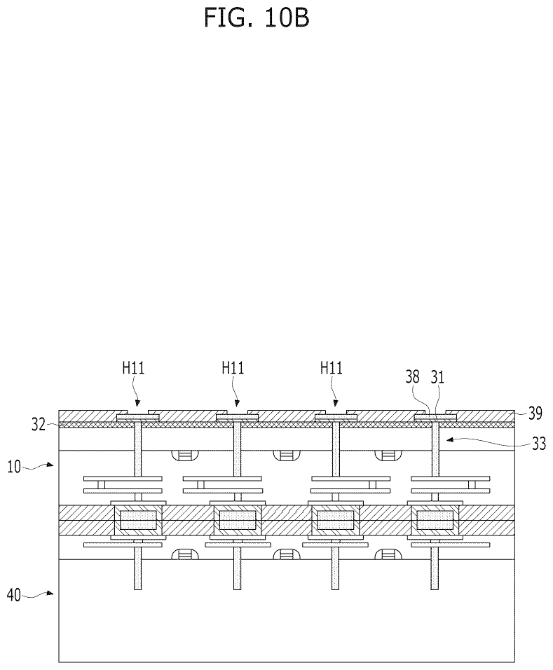

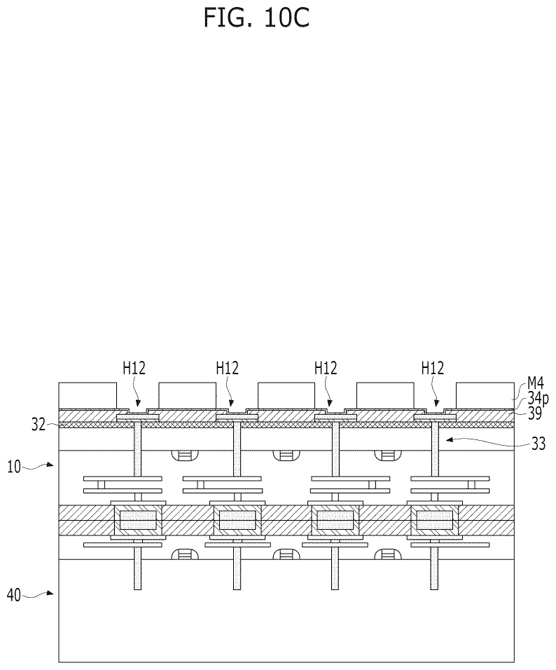

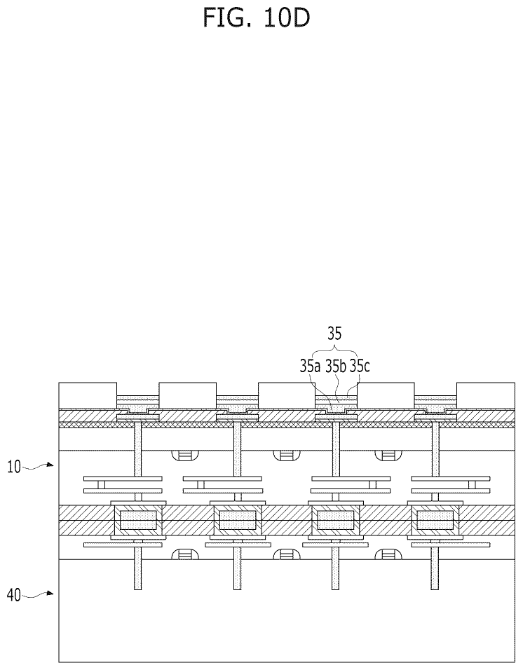

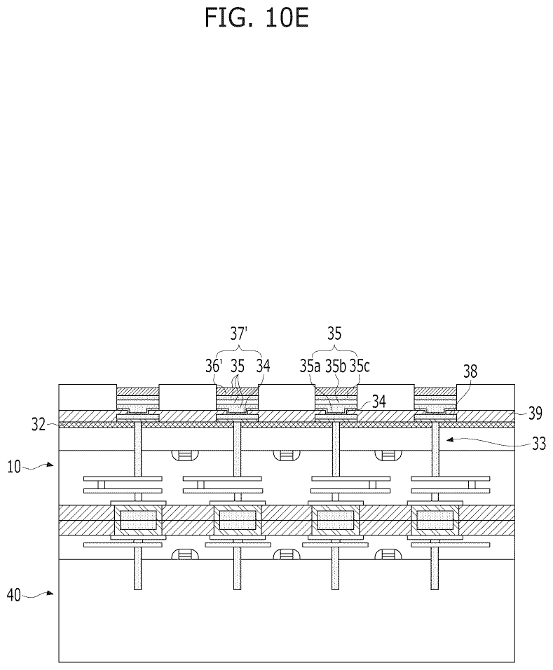

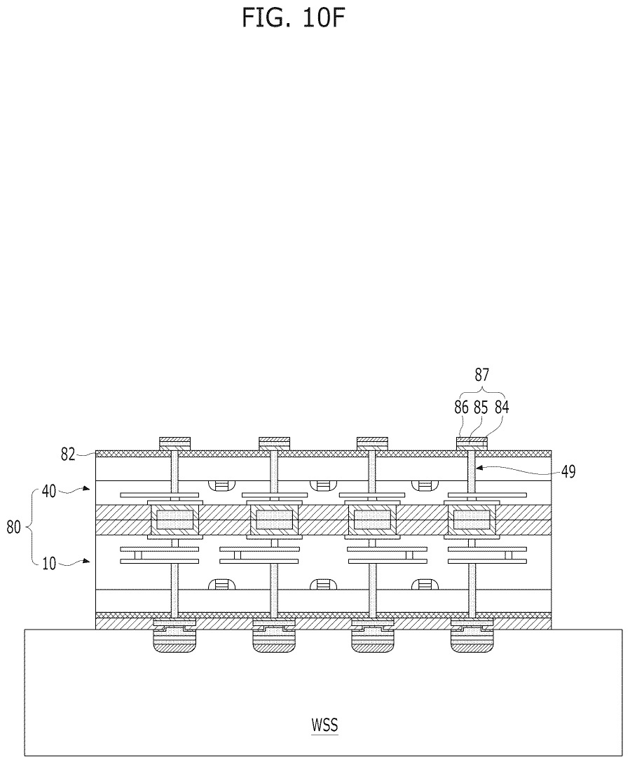

FIGS. 10A to 10F illustrate manufacturing and preparing a plurality of base-bottom die stack structures 80 by bonding the base die 10 and the bottom die 40 in a method of manufacturing a semiconductor die stack structure (104 in FIG. 11A) in accordance with an embodiment of the present disclosure.

Referring to FIG. 10A, the method may further include forming a preliminary semiconductor stack structure by performing the processes described with reference to FIGS. 8A to 8D, forming a preliminary base die back-side bump pad UBM layer 31p over the base die back-side passivation layer 32, forming a plating mask pattern M3, and forming base die back-side bump pads 38. The preliminary base die back-side bump pad UBM layer 31p may include a lower preliminary base die back-side bump pad UBM layer including titanium (Ti) or titanium tungsten (TiW) and an upper preliminary base die back-side bump pad UBM including copper (Cu). The plating mask pattern M3 may have holes H10 that are vertically aligned with respect to the bottom die through-electrodes 33. The base die back-side bump pads 38 may be formed by performing a plating process over the preliminary base die back-side bump pad UBM layer 31p to fill the lower portions of the holes H10. The base die back-side bump pads 38 may include copper (Cu) or nickel (Ni). According to one embodiment of the present disclosure, the base die back-side bump pads 38 may be formed of a single layer or a multi-layer including a copper (Cu) layer and/or a nickel (Ni) layer. According to another embodiment of the present disclosure, the base die back-side bump pad 38 may include a copper (Cu) layer and a capping metal layer formed over the copper (Cu) layer. The capping metal layer may include an oxidation-resistant and corrosion-resistant metal, such as gold (Au). Subsequently, the plating mask pattern M3 may be removed.

Referring to FIG. 10B, the method may further include removing the plating mask pattern M3, removing the exposed preliminary bottom die back-side pad UBM layer 78p under the plating mask pattern M3, and forming a base die top back-side passivation layer 39 over the base die back-side passivation layer 32. A portion of the preliminary base die back-side bump pad UBM layer 31p may form the remaining base die back-side bump pad UBM layer 31 below the base die back-side bump pads 38. The base die top back-side passivation layer 39 may have holes H11 exposing the base die back-side bump pads 38.

Referring to FIG. 10C, the method may further include forming a preliminary base die back-side UBM layer 34p over the exposed surfaces of the base top back-side passivation layer 39 and the base die back-side bump pads 38, and forming a plating mask pattern M4 having holes H12 vertically overlapping with the base die back-side bump pads 38.

Referring to FIG. 10D, the method may further include forming base die back-side bumps 35 by performing a plating process. The base die back-side bumps 35 may have a multi-layer structure. For example, it may include a bottom base die back-side bump 35a, a middle base die back-side bump 35b, and a top base die back-side bump 35c. According to one embodiment of the present disclosure, the bottom base die back-side bump 35a and the top base die back-side bump 35c may include the same metal. For example, the bottom base die back-side bump 35a and the top base die back-side bump 35c may include copper (Cu). The middle base die back-side bump 35b may include a metal that is different from those of the bottom base die back-side bump 35a and the top base die back-side bump 35c. For example, the middle base die back-side bump 35b may include nickel (Ni).

Referring to FIG. 10E, the method may further include forming base die back-side bump solders 36′ over the base die back-side bumps 35, removing the plating mask pattern M4, and removing the preliminary base die back-side UBM layer 34p exposed below the plating mask pattern M4. The base die back-side bump structures 37′ including the base die back-side UBM layer 34 and the base die back-side bump 35 and 36 may be formed. The base die back-side bump 35 and 36 may include the base die back-side bump metal 35 and the base die back-side bump solder 36′. Some of the base die back-side bump pads 38 may be exposed.

Referring to FIG. 10F, the method may further include forming bottom die back-side bump structures 87 by performing the processes described with reference to FIGS. 8F to 8H.

FIG. 11A illustrates a semiconductor die stack structure 104 fabricated using a base-bottom die stack structure 80, middle dies 50, and a top die 60 in accordance with one embodiment of the present disclosure, and FIG. 11B is an enlarged view of a portion of the semiconductor die stack structure 104 illustrated in FIG. 11A.

Referring to FIGS. 11A and 11B, the method may further include manufacturing a plurality of semiconductor die stack structures 104 by performing the processes described with reference to FIGS. 9A and 9B. The semiconductor die stack structure 104 may include a plurality of middle dies 50 and a top die 60 that are stacked over the base die 10 and the bottom die 40 that are bonded in a face-to-face manner. The semiconductor die stack structure 104 may include the bottom die 40, the middle dies 50, and the top die 60 that are directly stacked in a face-down manner over the base die 10 that is disposed in a face-up manner.

The base die 10 may be disposed in the lowermost portion of the semiconductor stack structure 104 in a face-up manner. The base die 10 may include a base substrate 11, base die circuit elements 12, a base die inter-layer dielectric layer 13, a base die front-side bonding dielectric layer 15, a base die front-side bonding pad structure 18, a base die back-side passivation layer 32, a base top back-side passivation layer 39, a base die through-electrode 33, and a base die back-side bump structure 37′. The base die back-side bump structure 37′ may include a base die back-side UBM layer 34 and a base die back-side bump 35 and 36′. The base die back-side bump 35 and 36′ may include a base die back-side bump metal 35 and a base die back-side bump solder 36′. The base die back-side UBM layer 34 may include a lower base die back-side UBM layer, such as titanium (Ti) or titanium nitride (TiW), and an upper base die back-side UBM layer, such as copper (Cu). The base die back-side bump metal 35 may include a bottom base die back-side bump 35a, a middle base die back-side bump 35b, and a top base die back-side bump 35c. The bottom base die back-side bump 35a and the top base die back-side bump 35c may include copper (Cu). The middle base die back-side bump 35b may include nickel (Ni). The base die back-side bump solder 36′ may include a solder material. The constituent elements of the reference numerals that are not described may be understood with reference to FIGS. 5F, 6G, and 9B.

According to an embodiment of the present disclosure, a semiconductor die stack structure fabricated through a wafer-to-wafer bonding process can be provided. In an embodiment, after the wafer-to-wafer bonding process is performed, a thinning process may be performed to provide a thin substrate and a short through-via structure. Accordingly, a semiconductor die-stack structure in an embodiment can be provided with excellent electrical characteristics that can be processed.

While the present disclosure has been described with respect to the specific embodiments, it will be apparent to those skilled in the art that various changes and modifications may be made without departing from the spirit and scope of the disclosure as defined in the following claims.

What is claimed is:

1. A method of manufacturing a semiconductor die stack structure, comprising:
preparing a base die including a base die substrate and a base die inter-layer dielectric layer;
forming a base die front-side bonding pad structure over the base die inter-layer dielectric layer;
preparing a bottom die having a bottom die substrate and a bottom die through-electrode;
forming a bottom die front-side bonding pad structure over a front-side of the bottom die substrate;
forming a base-bottom die stack structure in which the bottom die front-side bonding pad structure and the base die front-side bonding pad structure are directly in contact with each other by bonding the bottom die and the base die;
forming a base die through-electrode vertically passing through the base die substrate and electrically connected to the base die front-side bonding pad structure;
forming a base die back-side bump structure electrically connected to the base die through-electrode over a back-side of the base die substrate;
stacking a plurality of middle dies over the base die of the base-bottom die stack structure;
stacking a top die over the plurality of middle dies; and
forming a bottom die back-side bump structure electrically connected to the bottom die through-electrode.

2. The method of claim 1,
wherein the base die further includes base die circuit elements that are disposed over the base die substrate,
wherein the base die circuit elements include a base die transistor, a base die metal interconnection, a base die metal pad, and a base die metal via, and
wherein the base die front-side bonding pad structure is formed over the base die metal pad.

3. The method of claim 1, further comprising:
forming a base die front-side bonding dielectric layer over the base die inter-layer dielectric layer; and
forming a bottom die front-side bonding dielectric layer over the front-side of the bottom die substrate,
wherein the base die front-side bonding dielectric layer and the bottom die front-side bonding dielectric layer are directly in contact with each other.

4. The method of claim 3, wherein the forming of the base die front-side bonding pad structure includes:
forming a hole that exposes the base die metal pad in the base die front-side bonding dielectric layer;
conformally forming a base die front-side bonding pad seed layer in the hole;
forming a base die front-side bonding pad metal over the base die front-side bonding pad seed layer to fill the hole; and
planarizing an upper surface of the base die front-side bonding dielectric layer, an upper surface of the base die front-side bonding pad seed layer, and an upper surface of the base die front-side bonding pad metal.

5. The method of claim 3, wherein the forming of the bottom die front-side bonding pad structure includes:
forming a hole that exposes the bottom die substrate in the bottom die front-side bonding dielectric layer;
forming a bottom die front-side bonding pad seed layer in the hole;
forming a bottom die front-side bonding pad metal over the bottom die front-side bonding pad seed layer to fill the hole; and
planarizing an upper surface of the bottom die front-side bonding dielectric layer, an upper surface of the bottom die front-side bonding pad barrier layer, and an upper surface of the bottom die front-side bonding pad metal.

6. The method of claim 1, wherein the forming of the base die back-side bump structure includes:
exposing an end portion of the base die through-electrode by thinning the base die substrate of the base die of the base-bottom die stack structure;
forming a base die back-side under-bump metallurgy (UBM) layer over the exposed end portion of the base die through-electrode; and
forming a base die back-side bump over the base die back-side UBM layer.

7. The method of claim 1, wherein the forming of the bottom die back-side bump structure includes:
thinning the bottom die substrate to expose an end portion of the bottom die through-electrode; and
forming a bottom die back-side bump over the exposed end portion of the bottom die through-electrode.

8. The method of claim 1, wherein the forming of the bottom die back-side bump structure includes:
thinning the bottom die substrate to expose an end portion of the bottom die through-electrode;
forming a bottom die back-side pad over the exposed end portion of the bottom die through-electrode;
forming a bottom die back-side top passivation layer having a hole that exposes an upper surface of the bottom die back-side pad over the bottom die back-side passivation layer;
forming a bottom die back-side UBM layer in the hole of the bottom die back-side top passivation layer; and
forming a bottom die back-side bump to fill the hole over the bottom die back-side UBM layer.

9. The method of claim 1, wherein the semiconductor die stack structure includes:
the bottom die disposed in a face-up manner;
the base die disposed over the bottom die in a face-down manner; and
the middle dies and a top die disposed in a face-down manner over the base die, and
each of the bottom die and the base die has a first horizontal width, and
each of the middle dies and the top die has a second horizontal width, and
wherein the first horizontal width is greater than the second horizontal width.

10. A method of manufacturing a semiconductor die stack structure, comprising:
preparing a base die having a base die substrate and a base die inter-layer dielectric layer;
forming a base die front-side bonding pad structure over the base die inter-layer dielectric layer;
preparing a bottom die having a bottom die substrate and a bottom die through-electrode;
forming a bottom die front-side bonding pad structure over a front-side of the bottom die substrate;
forming a base-bottom die stack structure in which the bottom die front-side bonding pad structure and the base die front-side bonding pad structure are directly in contact with each other by bonding the bottom die and the base die;
forming a base die through-electrode vertically passing through the base die substrate and electrically connected to the base die front-side bonding pad structure;
forming a base die back-side bump structure electrically connected to the base die through-electrode over a back-side of the base die substrate;
forming a bottom die back-side bump structure over the base-bottom die stack structure;
stacking middle dies over the bottom die of the base-bottom die stack structure; and
stacking a top die over the middle dies.

11. The method of claim 10, wherein the base die further includes:
base die circuit elements disposed over the base die substrate, and
the base die circuit elements include a base die transistor, a base die metal interconnection, a base die metal pad, and a base die metal via, and
wherein the base die front-side bonding pad structure is formed over the base die metal pad.

12. The method of claim 10, wherein the bottom die further includes bottom die circuit elements disposed over the bottom die substrate.

13. The method of claim 10, further comprising:
forming a base die front-side bonding dielectric layer over the base die inter-layer dielectric layer; and
forming a bottom die front-side bonding dielectric layer over the front-side of the bottom die substrate,
wherein the base die front-side bonding dielectric layer and the bottom die front-side bonding dielectric layer are directly in contact with each other.

14. The method of claim 13, wherein the forming of the base die front-side bonding pad structure includes:
forming a hole that exposes the base die metal pad in the base die front-side bonding dielectric layer;
forming a base die front-side bonding pad seed layer in the hole;
forming a base die front-side bonding pad metal over the base die front-side bonding pad seed layer to fill the hole; and
planarizing an upper surface of the base die front-side bonding dielectric layer, an upper surface of the base die front-side bonding pad barrier layer, and an upper surface of the base die front-side bonding pad metal.

15. The method of claim 13, wherein the forming of the bottom die front-side bonding pad structure includes:
forming a hole that exposes a front-side of the bottom die substrate in the bottom die front-side bonding dielectric layer;
forming a bottom die front-side bonding pad seed layer in the hole;
forming a bottom die front-side bonding pad metal over the bottom die front-side bonding pad seed layer to fill the hole; and
planarizing an upper surface of the bottom die front-side bonding dielectric layer, an upper surface of the bottom die front-side bonding pad seed layer, and an upper surface of the bottom die front-side bonding pad metal.

16. The method of claim 10, wherein the forming of the base die back-side bump structure includes:
thinning the base die substrate of the base die of the base-bottom die stack structure to expose an end portion of the base die through-electrode;
forming a base die back-side under-bump metallurgy (UBM) layer over the exposed end portion of the base die through-electrode; and
forming a base die back-side bump over the base die back-side UBM layer.

17. The method of claim 10, wherein the forming of the bottom die back-side bump structure includes:
thinning the bottom die substrate to expose one end portion of the bottom die through-electrode;
forming a bottom die back-side UBM layer over the exposed one end portion of the bottom die through-electrode; and
forming a bottom die back-side bump over the bottom die back-side UBM layer.

18. The method of claim 10, wherein the semiconductor die stack structure includes:
the base die disposed in a face-up manner;
the bottom die disposed over the base die in a face-down manner; and
the middle dies and the top die disposed in a face-down manner over the bottom die,
wherein each of the bottom die and the base die has a first horizontal width,
wherein each of the middle dies and the top die has a second horizontal width, and
wherein the first horizontal width is greater than the second horizontal width.
